(19) United States
(12) Patent Application Publication
(10) Pub. No.: US 2026/0371900 A1
(43) Pub. Date: Nov. 19, 2026

(54) DISPLAY DEVICE AND ELECTRONIC DEVICE INCLUDING THE SAME

(71) Applicant: Samsung Display Co., LTD., Yongin-si (KR)

(72) Inventors: Seung Cheol KO, Yongin-si (KR); Young Suk LEE, Yongin-si (KR)

(21) Appl. No.: 19/462,262

(22) Filed: Jan. 28, 2026

(30) Foreign Application Priority Data
May 13, 2025 (KR) 10-2025-0062038

(51) Int. Cl. H10K 59/80

(52) U.S. Cl. CPC H10K 59/873

(57) ABSTRACT

A display device having a through hole defined therein includes an inorganic encapsulation area located to surround the through hole and including a plurality of tips disposed on a first organic film, and a test area including a metal pattern. The metal pattern includes a same material as the tips, and the metal pattern includes a first metal pattern portion having a first length in a first direction, and a second metal pattern portion having a second length in the first direction, where the first length is different from the second length.

### BACKGROUND

This application claims priority to Korean Patent Application No. 10-2025-0062038, filed on May 13, 2025, and all the benefits accruing therefrom under 35 U.S.C. 119, the content of which in its entirety is incorporated herein by reference.

### 1. Field

The present disclosure relates to a display device and an electronic device including the display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a light receiving display device such as a liquid crystal display device, a field emission display device, a light emitting display device, or the like, or a light emitting display device such as an organic light emitting display device including an organic light emitting element, an inorganic light emitting display device including an inorganic light emitting element such as an inorganic semiconductor, and an ultra-small light emitting display device including an ultra-small light emitting element.

### SUMMARY

Embodiments of the present disclosure provide a display device with improved operation reliability.

However, embodiments of the present disclosure are not restricted to those set forth herein. Other embodiments of the present disclosure will become more apparent to one of ordinary skill in the art to which the present disclosure pertains by referencing the detailed description of the present disclosure given below.

According to various embodiments of the present disclosure, a display device having a through hole defined therein includes an inorganic encapsulation area located to surround the through hole and including a plurality of tips disposed on a first organic film, and a test area including a metal pattern. In such embodiments, the metal pattern includes a same material as the tips, and the metal pattern includes a first metal pattern portion having a first length in a first direction, and a second metal pattern portion having a second length in the first direction, where the first length is different from the second length.

According to various embodiments of the present disclosure, the metal pattern may be located on the first organic film.

According to various embodiments of the present disclosure, in the test area, the metal pattern may be located on the first organic film, and the first organic film located in the test area may include a first protrusion located to be in contact with the first metal pattern portion, and a second protrusion located to be in contact with the second metal pattern portion.

According to various embodiments of the present disclosure, the first metal pattern portion may include a bottom surface at least partially exposed by the first protrusion, and the second metal pattern portion may include a bottom surface at least partially exposed by the second protrusion.

According to various embodiments of the present disclosure, a length of a bottom surface of the first metal pattern portion exposed by the first protrusion may be equal to a length of a bottom surface of the second metal pattern portion exposed by the second protrusion.

According to various embodiments of the present disclosure, the test area may have an undercut structure defined by a top surface of the first organic film, a side surface of the first protrusion, and a bottom surface of the first metal pattern portion.

According to various embodiments of the present disclosure, a length of the first protrusion in the first direction may be different from a length of the second protrusion in the first direction.

According to various embodiments of the present disclosure, the first length may be smaller than the second length, and a length of the first protrusion in the first direction may be smaller than a length of the second protrusion in the first direction.

According to various embodiments of the present disclosure, in the test area, the metal pattern may be located on the first organic film, a first overlapping length and a second overlapping length may be defined in the test area, the first overlapping length is different from the second overlapping length, the first overlapping length is a length in the first direction of a portion of a lower surface of the first metal pattern portion contacting the first organic film, and the second overlapping length is a length in the first direction of a portion of a lower surface of the second metal pattern portion contacting the first organic film.

According to various embodiments of the present disclosure, in the test area, the metal pattern may be located on the first organic film, a first exposure length and a second exposure length may be defined in the test area, the first exposure length may be different from the second exposure length, the first exposure length is a length in the first direction of a portion of a lower surface of the first metal pattern portion exposed by the first organic film, and the second exposure length is a length in the first direction of a portion of a lower surface of the second metal pattern portion exposed by the first organic film.

According to various embodiments of the present disclosure, in the test area, the metal pattern may be located on the first organic film, and in the test area, a first overlapping length, a second overlapping length, a first exposure length, and a second exposure length may be defined. In such embodiments, a sum of the first overlapping length and the first exposure length may be equal to a sum of the second overlapping length and the second exposure length. In such embodiments, the first overlapping length is a length in the first direction of a portion of a lower surface of the first metal pattern portion contacting the first organic film, the second overlapping length is a length in the first direction of a portion of a lower surface of the second metal pattern portion contacting the first organic film, the first exposure length is a length in the first direction of a portion of a lower surface of the first metal pattern portion exposed by the first organic film, and the second exposure length is a length in the first direction of a portion of a lower surface of the second metal pattern portion exposed by the first organic film.

According to various embodiments of the present disclosure, in the test area, the metal pattern may be located on the first organic film. In such embodiments, The metal pattern may include a reference metal pattern portion having a reference length in the first direction, the reference length is greater than the first length and the second length, the first organic film located in the test area may include a protrusion located to be in contact with the reference metal pattern portion, and a region including the reference metal pattern portion may have an undercut structure formed by a top surface of the first organic film, a side surface of the protrusion, and a bottom surface of the reference metal pattern portion.

According to various embodiments of the present disclosure, the tip may have a tip exposure length exposed by the first organic film, and a length of a bottom surface of the reference metal pattern portion exposed by the protrusion may be substantially the same as the tip exposure length.

According to various embodiments of the present disclosure, the display device may further include a display area including a plurality of pixels, and the pixel may include a first organic film, a connection electrode located on the first organic film, a second organic film located on the connection electrode, a pixel electrode located on the second organic film, a light emitting layer located on the pixel electrode, and a common electrode located on the light emitting layer. In such embodiments, the inorganic encapsulation area may have a groove defined between the plurality of tips, and the inorganic encapsulation area may further include a light emitting layer remnant located in the groove and including a same material as the light emitting layer, and a common electrode remnant located on the light emitting layer remnant and including a same material as the common electrode.

According to various embodiments of the present disclosure, the tip may include a same material as the connection electrode.

According to various embodiments of the present disclosure, an electronic device includes a processor which provides an image signal, a display module which receives the image signal from the processor and displays an image, and a power module which supplies power to the display module. In such embodiments, the display module has a through hole defined therein, and the display module includes an inorganic encapsulation area located to surround the through hole and including a plurality of tips disposed on a first organic film, and a test area including a metal pattern. In such embodiments, the metal pattern includes a same material as the tips, and the metal pattern includes a first metal pattern portion having a first length in a first direction, and a second metal pattern portion having a second length in the first direction, and the first length is different from the second length.

According to various embodiments of the present disclosure, in the test area, the metal pattern may be located on the first organic film, and the first organic film located in the test area may include a first protrusion located to be in contact with the first metal pattern portion, and a second protrusion located to be in contact with the second metal pattern portion.

According to various embodiments of the present disclosure, the test area may include an undercut structure defined by a top surface of the first organic film, a side surface of the first protrusion, and a bottom surface of the first metal pattern portion.

According to various embodiments of the present disclosure, in the test area, the metal pattern may be located on the first organic film, a first overlapping length and a second overlapping length may be defined in the test area, the first overlapping length is different from the second overlapping length, the first overlapping length is a length in the first direction of a portion of a lower surface of the first metal pattern portion contacting the first organic film, and the second overlapping length is a length in the first direction of a portion of a lower surface of the second metal pattern portion contacting the first organic film.

According to various embodiments of the present disclosure, in the test area, the metal pattern may be located on the first organic film, a first exposure length and a second exposure length may be defined in the test area, the first exposure length may be different from the second exposure length, the first exposure length is a length in the first direction of a portion of a lower surface of the first metal pattern portion exposed by the first organic film, and the second exposure length is a length in the first direction of a portion of a lower surface of the second metal pattern portion exposed by the first organic film.

A display device according to an embodiment of the present disclosure may improve the accuracy of measuring a tip exposure length. Accordingly, permeation of moisture or the like through a through hole in the display device may be effectively prevented, and operation reliability of the display device may be improved.

### BRIEF DESCRIPTION OF THE DRAWINGS

The above and other features of embodiments of the present disclosure will become more apparent by describing in detail embodiments thereof with reference to the attached drawings, in which:

FIG. 1 is a plan view illustrating a display panel and a driving integrated circuit (IC) according to an embodiment of the present disclosure;

FIG. 2 is a cross-sectional view showing an example of a display device in which a circuit board according to an embodiment of the present disclosure is bent;

FIG. 3 is a cross-sectional view illustrating an example of a display area of a display panel according to an embodiment of the present disclosure;

FIG. 4 is a partially enlarged view showing area I of FIG. 1;

FIG. 5 is a cross-sectional view illustrating an example of a display panel taken along line X-X′ of FIG. 4;

FIGS. 6 to 9 are cross-sectional views illustrating an embodiment of a process of forming a first inorganic encapsulation area;

FIG. 10 is a plan view illustrating a test area according to an embodiment of the present disclosure;

FIG. 11 is a cross-sectional view illustrating a portion taken along line Y1-Y1′ of FIG. 10;

FIG. 12 is a partially enlarged view of area K of FIG. 11;

FIG. 13 is a plan view illustrating a process of forming a test area of FIG. 10 according to an embodiment of the present disclosure;

FIGS. 14 to 16 are cross-sectional views illustrating a process of forming a test area of FIG. 10 according to an embodiment of the present disclosure;

FIG. 17 is a plan view showing a modified example of FIG. 10;

FIG. 18 is a cross-sectional view illustrating a portion taken along line Y3-Y3′ of FIG. 17;

FIG. 19 is a plan view illustrating a process of forming a test area according to the modified example of FIG. 10;

FIGS. 20 to 22 are cross-sectional views illustrating a process of forming a test area according to the modified example of FIG. 10;

FIG. 23 is a plan view illustrating a test area according to another embodiment of the present disclosure;

FIGS. 24 and 25 each include a plan view and a cross-sectional view illustrating a process of forming a test area of FIG. 23 according to an embodiment of the present disclosure;

FIG. 26 is a plan view showing a modified example of FIG. 23;

FIGS. 27 and 28 each include a plan view and a cross-sectional view illustrating a process of forming a test area according to the modified example of FIG. 23;

FIG. 29 is a cross-sectional view showing a reference metal pattern portion of FIG. 23 according to an embodiment of the present disclosure;

FIG. 30 is a cross-sectional view showing a fifth metal pattern portion of FIG. 23 according to an embodiment of the present disclosure;

FIG. 31 is a cross-sectional view showing a fourth metal pattern portion of FIG. 23 according to an embodiment of the present disclosure;

FIG. 32 is a block diagram of an electronic device according to an embodiment of the present disclosure; and

FIG. 33 is schematic views of electronic devices according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

Throughout this specification, the same or like reference numerals refer to the same or like components, and any repetitive detailed description thereof may be omitted or simplified. The shapes, sizes, proportions, angles, numbers, etc. disclosed in the drawings to illustrate embodiments are examples and are not intended to be limiting to those shown herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Each of the features of the various embodiments disclosed herein may be combined or combinable with each other, in part or in whole, and may be technically interlocked and operated in a variety of ways, and each embodiment may be practiced independently of or in conjunction with one another.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Various embodiments will hereinafter be described in detail with reference to the accompanying drawings.

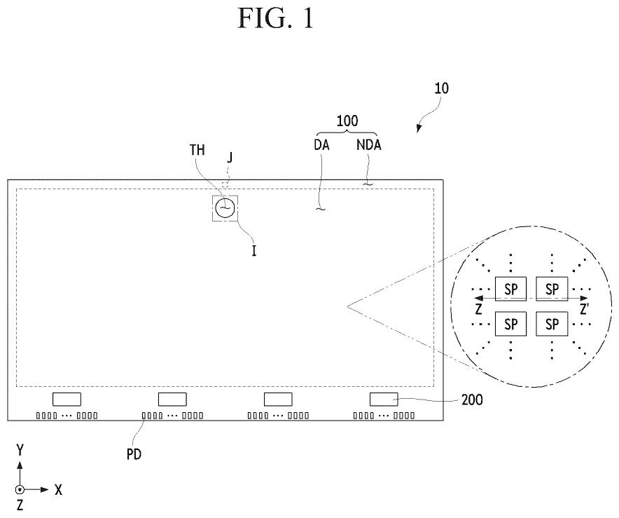

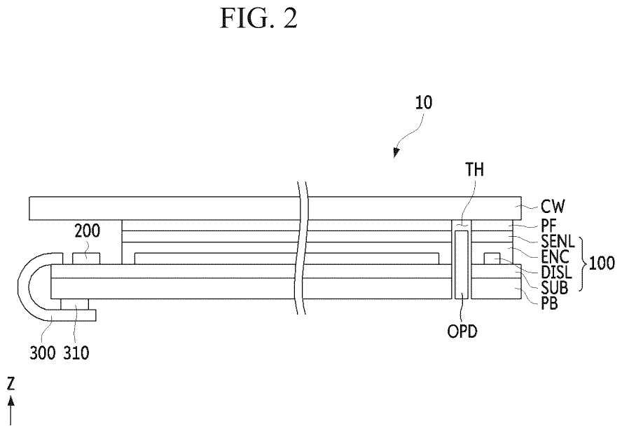

FIG. 1 is a plan view illustrating a display panel and a driving integrated circuit (IC) according to an embodiment of the present disclosure. FIG. 2 is a cross-sectional view showing an example of a display device in which a circuit board according to an embodiment of the present disclosure is bent.

Referring to FIGS. 1 and 2, a through hole TH may be formed in a display device 10 according to an embodiment of the present disclosure. That is, a display device 10 according to an embodiment of the present disclosure may have the through hole TH defined therein. The through hole TH may be a hole capable of transmitting light, and may be a physical hole penetrating not only a display panel 100 but also a panel lower cover PB and a polarizing film PF. However, embodiments of the present disclosure are not limited thereto, and the through hole TH may penetrate the panel lower cover PB but may not penetrate the display panel 100 and the polarizing film PF. A cover window CW may be located to cover the through hole TH.

The through hole TH may penetrate (or be defined or formed through) a substrate SUB, a thin film transistor layer TFTL, an encapsulation layer ENC, and a sensor electrode layer SENL of the display panel 100.

An electronic device including the display device 10 according to an embodiment may further include an optical device OPD located in the through hole TH. The electronic device according to an embodiment may be a portable electronic device such as a mobile phone, a smart phone, a tablet personal computer (PC), a smart watch, a watch phone, a mobile communication terminal, an electronic notebook, an electronic book, a portable multimedia player (PMP), a navigation device, and an ultra mobile PC (UMPC), as well as a television (TV), a laptop computer, a monitor, a billboard, an Internet of Things (IOT) device. However, embodiments of the present disclosure are not limited thereto.

The optical device OPD may be spaced apart from the display panel 100, the panel lower cover PB, and the polarizing film PF. The optical device OPD may be an optical sensor that senses light incident through the through hole TH, such as a proximity sensor, an illuminance sensor, and a camera sensor.

Referring to FIG. 2, the display device 10 according to an embodiment of the present disclosure may include the display panel 100, the polarizing film PF, a cover window CW, and the panel lower cover PB. The display panel 100 may include the substrate SUB, a display layer DISL, the encapsulation layer ENC, and the sensor electrode layer SENL.

In an embodiment, the substrate SUB may include or be formed of a hard material. In an embodiment, for example, the substrate SUB may include glass. The substrate SUB may include ultra thin glass (UTG) having a thickness of approximately 200 micrometers (μm) or less.

In another embodiment, the substrate SUB may include or be formed of a flexible material. In an embodiment, for example, the substrate SUB may include polyimide.

The display layer DISL may be located on a first surface of the substrate SUB. The display layer DISL may be a layer that emits light for displaying an image. The display layer DISL may include the thin film transistor layer TFTL in which thin film transistors are formed, and a light emitting element layer EML in which light emitting elements emitting light are located in emission areas.

In the display area DA of the display layer DISL, scan lines, data lines, power lines, or the like for the emission areas to emit light may be located. In the non-display area NDA of the display layer DISL, a scan driving circuit unit outputting scan signals to the scan lines, fan-out lines connecting the data lines and the driving IC 200, or the like may be located.

The encapsulation layer ENC may effectively prevent oxygen and/or moisture from permeating into the light emitting element layer EML of the display layer DISL. The encapsulation layer ENCL may be a layer for encapsulating the light emitting element layer EML of the display layer DISL. The encapsulation layer ENC may be located on the display layer DISL. The encapsulation layer ENC may be located on the top surfaces and the side surfaces of the display layer DISL. The encapsulation layer ENC may be located to cover the display layer DISL.

The sensor electrode layer SENL may be located on the display layer DISL. The sensor electrode layer SENL may include sensor electrodes. The sensor electrode layer SENL may sense a user's touch using sensor electrodes.

The polarizing film PF may be located on the display panel 100 to reduce reflection of external light. In an embodiment, although not shown, the polarizing film PF may include a first base member, a linear polarization plate, a phase retardation film such as a quarter-wave plate (λ/4 plate), and a second base member. The first base member, the phase retardation film, the linear polarization plate, and the second base member of the polarizing film PF may be sequentially stacked on the display panel 100.

The cover window CW may be located on the polarizing film PF. The cover window CW may be attached onto the polarizing film PF by a transparent adhesive member such as an optically clear adhesive (OCA) film.

The panel lower cover PB may be located on a second surface of the substrate SUB of the display panel 100. The second surface of the substrate SUB may be a surface opposite to the first surface thereof. The panel lower cover PB may be attached to the second surface of the substrate SUB of the display panel 100 through an adhesive member. The adhesive member may be a pressure sensitive adhesive (PSA).

In an embodiment although not shown, the panel lower cover PB may include at least one selected from a light blocking member for absorbing light incident from the outside, a buffer member for absorbing an impact from the outside, or a heat dissipation member for efficiently dissipating heat from the display panel 100.

The light blocking member may be located under the display panel 100. The light blocking member may block light transmission, thereby effectively preventing components (e.g., a circuit board 300 and the like) located under the light blocking member from being viewed from the top of the display panel 100. The light blocking member may include a light absorbing material such as a black pigment, black dyes or the like.

The buffer member may be located under the light blocking member. The buffer member may absorb an external impact to effectively prevent the display panel 100 from being damaged. The buffer member may be formed as a single layer or multiple layers. In an embodiment, for example, the buffer member may include polymer resin such as polyurethane (PU), polycarbonate (PC), polypropylene (PP), or polyethylene (PE) or may include an elastic material such as a foamed sponge obtained from rubber, a urethane-based material, or an acrylic material.

The heat dissipation member may be located under the buffer member. The heat dissipation member may include a first heat dissipation layer including graphite, carbon nanotubes or the like, and a second heat dissipation layer formed as a metal thin film including, for example, copper, nickel, ferrite, or silver which can shield electromagnetic waves and has high thermal conductivity.

The circuit board 300 may be bent toward the bottom of the display panel 100. The circuit board 300 may be attached to the bottom surface of the panel lower cover PB by an adhesive member 310. The adhesive member 310 may be a pressure sensitive adhesive.

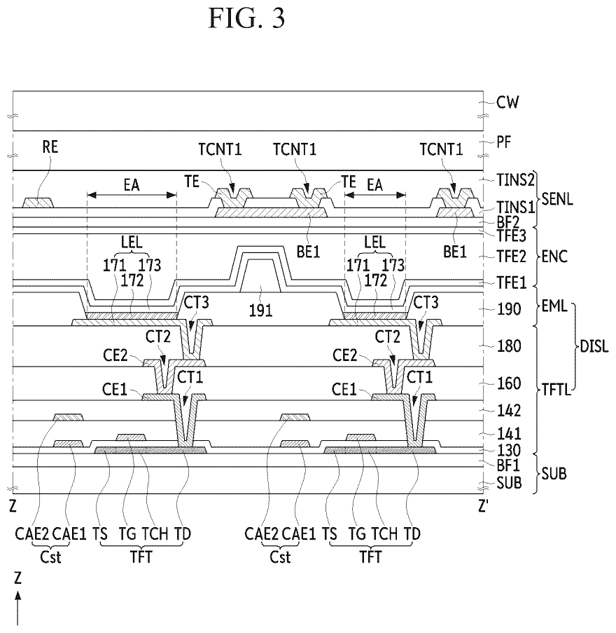

FIG. 3 is a cross-sectional view illustrating an example of a display area of a display panel according to an embodiment of the present disclosure. Particularly, FIG. 3 shows an example of a display panel taken along line Z-Z′ of FIG. 1.

Referring to FIG. 3, the display panel 100 according to an embodiment of the present disclosure may be an organic light emitting display panel including a light emitting element LEL including an organic light emitting layer 172.

The display layer DISL may include the thin film transistor layer TFTL including a plurality of thin film transistors and the light emitting element layer EML including a plurality of light emitting elements.

A first buffer film BF1 may be located on the substrate SUB. The first buffer film BF1 may include an inorganic material such as a silicon nitride layer, a silicon oxynitride layer, a silicon oxide layer, a titanium oxide layer and an aluminum oxide layer. Alternatively, the first buffer film BF1 may be formed as a multilayer in which a plurality of layers at least two selected from a silicon nitride layer, a silicon oxynitride layer, a silicon oxide layer, a titanium oxide layer and an aluminum oxide layer are alternately stacked.

An active layer including a channel region TCH, a source region TS, and a drain region TD of the thin film transistor TFT may be located on the first buffer film BF1. The active layer may include polycrystalline silicon, monocrystalline silicon, low-temperature polycrystalline silicon, amorphous silicon, or an oxide semiconductor material. In an embodiment where the active layer includes polycrystalline silicon or an oxide semiconductor material, the source region TS and the drain region TD of the active layer may be conductive regions doped with ions or impurities and having conductivity.

The gate insulating film 130 may be located on the active layer of the thin film transistor TFT. The gate insulating film 130 may be formed as (or defined by) an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of a capacitor Cst, and scan lines may be located on the gate insulating film 130. The gate electrode TG of the thin film transistor TFT may overlap the channel region TCH in a third direction or a thickness direction of the substrate SUB (e.g., Z-axis direction). The first gate metal layer may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

A first interlayer insulating film 141 may be located on the first gate metal layer. The first interlayer insulating film 141 may be formed as an inorganic film, for example, a silicon nitride layer, a silicon oxynitride layer, a silicon oxide layer, a titanium oxide layer, or an aluminum oxide layer. The first interlayer insulating film 141 may include or be defined by a plurality of inorganic films.

A second gate metal layer including a second capacitor electrode CAE2 of the capacitor Cst may be located on the first interlayer insulating film 141. The second capacitor electrode CAE2 may overlap the first capacitor electrode CAE1 in the third direction (e.g., Z-axis direction). Therefore, the capacitor Cst may be formed (or collectively defined) by the first capacitor electrode CAE1, the second capacitor electrode CAE2, and an inorganic insulating dielectric film located between the first capacitor electrode CAE1 and the second capacitor electrode CAE2 to serve as a dielectric film. The second gate metal layer may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

A second interlayer insulating film 142 may be located on the second gate metal layer. The second interlayer insulating film 142 may be formed as an inorganic film, for example, a silicon nitride layer, a silicon oxynitride layer, a silicon oxide layer, a titanium oxide layer, or an aluminum oxide layer. The second interlayer insulating film 142 may include or be defined by a plurality of inorganic films.

The first data metal layer including a first connection electrode CE1 and the data lines may be located on the second interlayer insulating film 142. The first connection electrode CE1 may be connected to the drain region TD through a first contact hole CT1 penetrating the gate insulating film 130, the first interlayer insulating film 141, and the second interlayer insulating film 142. The first data metal layer may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

A first organic film 160 for flattening the stepped portion due to the thin film transistors TFT may be located on the first connection electrode CE1. The first organic film 160 may be formed as an organic film such as acrylic resin, epoxy resin, phenolic resin, polyamide resin, polyimide resin and the like.

In an embodiment, a second data metal layer including a second connection electrode CE2 may be located on the first organic film 160. The second data metal layer may be connected to the first connection electrode CE1 through a second contact hole CT2 penetrating (i.e., defined or formed through) the first organic film 160. The second data metal layer may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

A second organic film 180 may be located on the second connection electrode CE2. The second organic film 180 may be formed as an organic film such as acrylic resin, epoxy resin, phenolic resin, polyamide resin, polyimide resin and the like.

In another embodiment, the second data metal layer including the second connection electrode CE2 and the second organic film 180 may be omitted.

The light emitting element layer EML may be located on the thin film transistor layer TFTL. The light emitting element layer EML may include light emitting elements LEL and a bank 190.

Each of the light emitting elements LEL may include a pixel electrode 171, the light emitting layer 172, and a common electrode 173. Each of the emission areas EA may be an area in which the pixel electrode 171, the light emitting layer 172, and the common electrode 173 are sequentially stacked such that the holes from the pixel electrode 171 and the electrons from the common electrode 173 are combined with each other to emit light. In this case, the pixel electrode 171 may be an anode electrode, and the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

In an embodiment having a top emission structure that emits light toward the common electrode 173 with respect to the light emitting layer 172, the pixel electrode 171 may be formed as a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, or a stacked structure (ITO/APC/ITO) of APC alloy and ITO to increase the reflectivity. The APC alloy is an alloy of silver (Ag), palladium (Pd) and copper (Cu).

In an embodiment, the bank 190 serves to define the emission areas EA of the pixels. In such an embodiment, the bank 190 may be formed to expose a partial region of the pixel electrode 171 on the second organic film 180. The bank 190 may cover the edge of the pixel electrode 171. The bank 190 may be located in the third contact hole CT3. That is, the third contact hole CT3 may be filled with the bank 190. The bank 190 may be formed as an organic film such as acrylic resin, epoxy resin, phenolic resin, polyamide resin, polyimide resin and the like.

A spacer 191 may be located on the bank 190. The spacer 191 may serve to support a mask during a process of manufacturing the light emitting layer 172. The spacer 191 may be formed as an organic film such as acrylic resin, epoxy resin, phenolic resin, polyamide resin, polyimide resin and the like. In an embodiment, the spacer 191 may include a same material as the bank 190, but embodiments of the present disclosure are not limited thereto.

The light emitting layer 172 may be formed on the pixel electrode 171. The light emitting layer 172 may include an organic material to emit light of a selected color. In an embodiment, for example, the light emitting layer 172 may include a hole transporting layer, an organic material layer, and an electron transporting layer. The organic material layer may include a host and a dopant. The organic material layer may include a material that emits selected light, and may be formed using a phosphorescent material or a fluorescent material.

The common electrode 173 may be formed on the light emitting layer 172. The common electrode 173 may be formed to cover the light emitting layer 172. The common electrode 173 may be a common layer formed in common on the emission areas EA. A capping layer may be formed on the common electrode 173.

In an embodiment having the top emission structure, the common electrode 173 may include a transparent conductive material (TCO) such as ITO or IZO capable of transmitting light or a semi-transmissive conductive material such as magnesium (Mg), silver (Ag), or an alloy of magnesium (Mg) and silver (Ag). In an embodiment where the common electrode 173 includes a semi-transmissive conductive material, the light emission efficiency can be increased due to a micro-cavity effect.

The encapsulation layer ENC may be formed on the light emitting element layer EML. The encapsulation layer ENC may include at least one inorganic film TFE1 and TFE3 to prevent oxygen or moisture from permeating into the light emitting element layer EML. In addition, the encapsulation layer ENC may include at least one organic film to protect the light emitting element layer EML from foreign substances such as dust. In an embodiment, for example, the encapsulation layer ENC may include a first encapsulation inorganic film TFE1, an encapsulation organic film TFE2, and a second encapsulation inorganic film TFE3.

The first encapsulation inorganic film TFE1 may be located on the common electrode 173, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as multiple films in which at least one inorganic layer selected from a silicon nitride layer, a silicon oxynitride layer, a silicon oxide layer, a titanium oxide layer and an aluminum oxide layer are alternately stacked. The encapsulation organic film TFE2 may be an organic film, and may include at least one selected from acrylic resin, epoxy resin, phenolic resin, polyamide resin, polyimide resin or the like.

The sensor electrode layer SENL is located on the encapsulation layer ENC. The sensor electrode layer SENL may include sensor electrodes TE and RE.

In an embodiment, a second buffer film BF2 may be located on the encapsulation layer ENC. The second buffer film BF2 may include at least one inorganic film. In an embodiment, for example, the second buffer film BF2 may be formed as multiple films in which at least one inorganic layer selected from a silicon nitride layer, a silicon oxynitride layer, a silicon oxide layer, a titanium oxide layer and an aluminum oxide layer are alternately stacked. In another embodiment, the second buffer film BF2 may be omitted.

First connection portions BE1 may be located on the second buffer film BF2. The first connection portions BE1 may be formed as a single layer including at least one selected from molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

A first sensor insulating film TINS1 may be located on the first connection portions BE1. The first sensor insulating film TINS1 may be formed as an inorganic film, and may include, for example, at least one selected from a silicon nitride layer, a silicon oxynitride layer, a silicon oxide layer, a titanium oxide layer, or an aluminum oxide layer.

The sensor electrodes, that is, the driving electrodes TE and the sensing electrodes RE may be located on the first sensor insulating film TNIS1. In addition, dummy patterns may be located on the first sensor insulating film TNIS1. The driving electrodes TE, the sensing electrodes RE, and the dummy patterns do not overlap the emission areas EA. The driving electrodes TE, the sensing electrodes RE, and the dummy patterns may be formed as a single layer including at least one selected from molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

A second sensor insulating film TINS2 may be located on the driving electrodes TE, the sensing electrodes RE, and the dummy patterns. The second sensor insulating film TINS2 may include at least one selected from an inorganic film or an organic film. The inorganic film may include a silicon nitride layer, a silicon oxynitride layer, a silicon oxide layer, a titanium oxide layer, or an aluminum oxide layer. The organic film may include acrylic resin, epoxy resin, phenolic resin, polyamide resin, or polyimide resin.

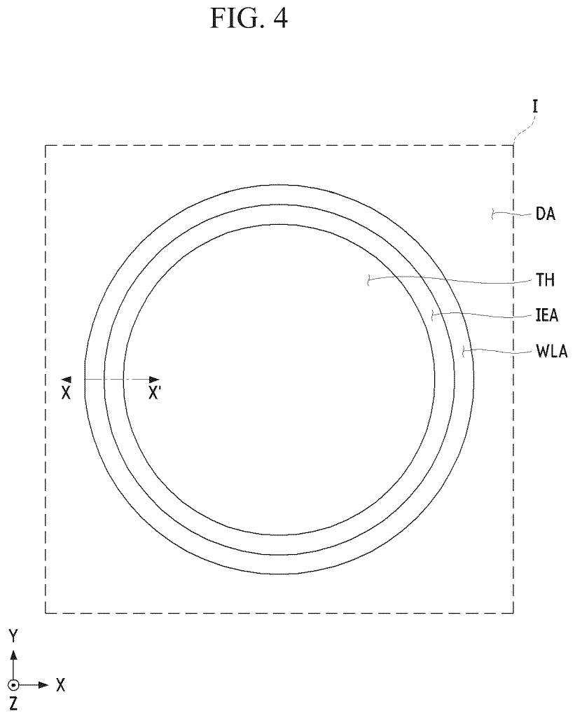

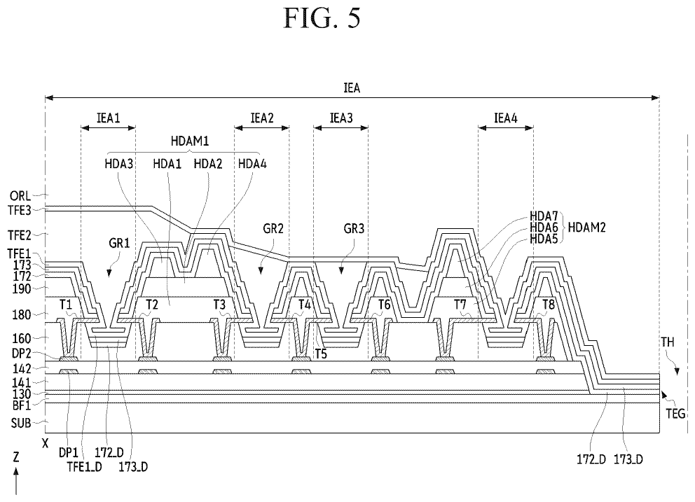

FIG. 4 is a partially enlarged view showing area I of FIG. 1. FIG. 5 is a cross-sectional view illustrating an example of a display panel taken along line X-X′ of FIG. 4.

Referring to FIGS. 4 and 5, the display panel according to an embodiment of the present disclosure may include an inorganic encapsulation area IEA surrounding the through hole TH and a wiring area WLA surrounding the inorganic encapsulation area IEA in a plan view or when viewed in the Z-axis direction.

The inorganic encapsulation area IEA may be a layer for effectively preventing oxygen or moisture from permeating into the light emitting element layer EML of the display layer DISL due to the through hole TH. In an embodiment, for example, the first encapsulation inorganic film TFE1 and the second encapsulation inorganic film TFE3 of the encapsulation layer ENC may be in contact with each other to effectively prevent the permeation of oxygen or moisture.

The inorganic encapsulation area IEA may include at least one dam, at least one tip, and at least one groove.

The wiring area WLA may be an area in which bypass lines due to the through hole TH are located. Some of the bypass lines may be connected to data lines, and some others of the bypass lines may be connected to a second power line to which a second source voltage higher than the first source voltage is applied. Yet some others of the bypass lines may be connected to the scan lines. The wiring area WLA may be surrounded by the display area DA.

A first dummy pattern DP1 may include a same material as the second gate metal layer including the second capacitor electrode CAE2 of the capacitor Cst and may be located in (or directly on) a same layer as the second gate metal layer. In an embodiment, for example, the first dummy pattern DP1 may be located on the first interlayer insulating film 141. The first dummy pattern DP1 may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

The second dummy pattern DP2 may include a same material as the first data metal layer including the first connection electrode CE1 and the data lines and may be located in (or directly on) a same layer as the first data metal layer. In an embodiment, for example, the second dummy pattern DP2 may be located on the second interlayer insulating film 142. The second dummy pattern DP2 may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

The second dummy pattern DP2 may overlap the first dummy pattern DP1 in the third direction (e.g., Z-axis direction).

The first to eighth tips T1 to T8 may include a same material as the second data metal layer including the second connection electrode CE2 and may be located in (or directly on) a same layer as the second data metal layer. In an embodiment, for example, the first to eighth tips T1 to T8 may be located on the first organic film 160. The first to eighth tips T1 to T8 may be formed as a single layer or multiple layers, each layer including at least one selected from molybdenum (Mo), aluminum (Al), chromium (Cr), gold (Au), titanium (Ti), nickel (Ni), neodymium (Nd) and copper (Cu) or an alloy thereof.

Each of the first to eighth tips T1 to T8 may be connected to the second dummy pattern DP2 through a contact hole penetrating the first organic film 160. Each of the first to eighth tips T1 to T8 may include an eaves structure in which the top surface and the bottom surface are exposed without being covered by the first organic film 160, the second organic film 180, the first dam HDAM1, and the second dam HDAM2. At least some of the plurality of tips may be integrally formed with each other as a single unitary indivisible part. In an embodiment, for example, the fourth tip T4 and the fifth tip T5 may be integrally formed as a single unitary indivisible part. Each of the first to eighth tips T1 to T8 may be a protruding pattern or a trench pattern for forming a groove (or trench). The eighth tip T8 may be an outermost structure, among the first to eighth tips T1 to T8, adjacent to an edge TEG of the through hole TH. The eighth tip T8 is illustrated as an outermost structure adjacent to the edge TEG of the through hole TH, but embodiments of the present disclosure are not limited thereto. In an embodiment, for example, where the seventh tip T7 and the eighth tip T8 are omitted, the outermost structure adjacent to the edge TEG of the through hole TH may be the second dam HDAM2 for preventing overflow of the encapsulation organic film TFE2 of the encapsulation layer ENC. In another embodiment, where the seventh tip T7 and the eighth tip T8 are omitted, the outermost structure adjacent to the edge TEG of the through hole TH may be a groove for disconnecting the light emitting layer 172 and the common electrode 173.

A distance from the eighth tip T8 to the edge TEG of the through hole TH may be approximately 300 μm. A through hole edge area may be defined between the eighth tip T8 and the edge TEG of the through hole TH.

A first groove GR1 may be formed between the first tip T1 and the second tip T2, a second groove GR2 may be formed between the third tip T3 and the fourth tip T4, and a third groove GR3 may be formed between the fifth tip T5 and the sixth tip T6. The first groove GR1 may have an eaves structure formed by the first tip T1 and the second tip T2, the second groove GR2 may have an eaves structure formed by the third tip T3 and the fourth tip T4, and the third groove GR3 may have an eaves structure formed by the fifth tip T5 and the sixth tip T6.

In an embodiment, since the light emitting layer 172 is deposited by evaporation and the common electrode 173 is deposited by sputtering, the light emitting layer 172 and the common electrode 173 may be located to be disconnected at each of the first to third grooves GR1, GR2, and GR3 because the step coverage is low. In such an embodiment, the first encapsulation inorganic film TFE1 and the third encapsulation inorganic film TFE3 may be deposited by chemical vapor deposition, atomic layer deposition, or the like, and thus may be formed to be continuous without being disconnected in each of the first to third grooves GR1, GR2, and GR3 because the step coverage is high. Step coverage refers to the ratio of the degree of thin film coated on an inclined portion to the degree of thin film coated on a flat portion. The light emitting layer 172, a disconnected light emitting layer remnant 172_D, the common electrode 173, and a disconnected common electrode remnant 173_D may be located in the first to third grooves GR1, GR2, and GR3, respectively.

The first dam HDAM1 may include first to fourth sub-dams HDA1, HDA2, HDA3, and HDA4. The first sub-dam HDA1 may be located on the first organic film 160 and may include a same material as the second organic film 180. The first sub-dam HDA1 may be located on the second tip T2 and the third tip T3. The second sub-dam HDA2 may be located on the first sub-dam HDA1 and may include a same material as the bank 190. The third sub-dam HDA3 and the fourth sub-dam HDA4 may be located on the second sub-dam HDA2 and may include a same material as the spacer 191, but are not limited thereto. The fourth sub-dam HDA4 may be located closer to the through hole TH than the third sub-dam HDA3. The thickness of the fourth sub-dam HDA4 may be greater than the thickness of the third sub-dam HDA3.

The second dam HDAM2 may include fifth to seventh sub-dams HDA5, HDA6, and HDA7. The fifth sub-dam HDA5 may be located on the first organic film 160 and may include a same material as the second organic film 180. The fifth sub-dam HDA5 may be located on the seventh tip T7. The sixth sub-dam HDA6 may be located on the fifth sub-dam HDA5 and may include a same material as the bank 190. The seventh sub-dam HDA7 may be located on the sixth sub-dam HDA6 and may include a same material as the spacer 191, but is not limited thereto.

The overflow of the encapsulation organic film TFE2 into the through hole TH may be effectively prevented by the first dam HDAM1 and the second dam HDAM2.

The light emitting layer remnant 172_D, the common electrode remnant 173_D, the first encapsulation inorganic film TFE1, and the second encapsulation inorganic film TFE3 may extend to the edge TEG of the through hole TH. The end of the light emitting layer remnant 172_D, the end of the common electrode remnant 173_D, the end of the first encapsulation inorganic film TFE1, or the end of the second encapsulation inorganic film TFE3 may coincide (e.g., aligned in the third direction) with the edge TEG of the through hole TH.

In such an embodiment, since the light emitting layer 172 and the common electrode 173 are disconnected in the first to fourth grooves GR1, GR2, GR3, and GR4 formed by the first to eighth tips T1 to T8, respectively, it is possible to effectively prevent the light emitting layer 172 and the common electrode 173 exposed through the through hole TH from being a path through which oxygen, moisture, or the like permeates.

In an embodiment, an organic planarization layer may be located on the encapsulation layer ENC. Due to the organic planarization layer, a polarizing film may be easily attached onto the organic planarization layer.

The organic planarization layer may be formed as an organic film such as acryl resin, epoxy resin, phenolic resin, polyamide resin, polyimide resin and the like. In an embodiment, for example, the organic planarization layer and the second sensor insulating film described above may include a same material as each other, and may be formed simultaneously by a same process.

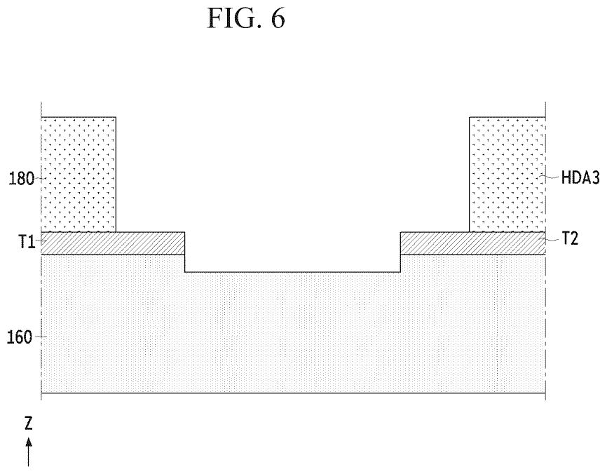

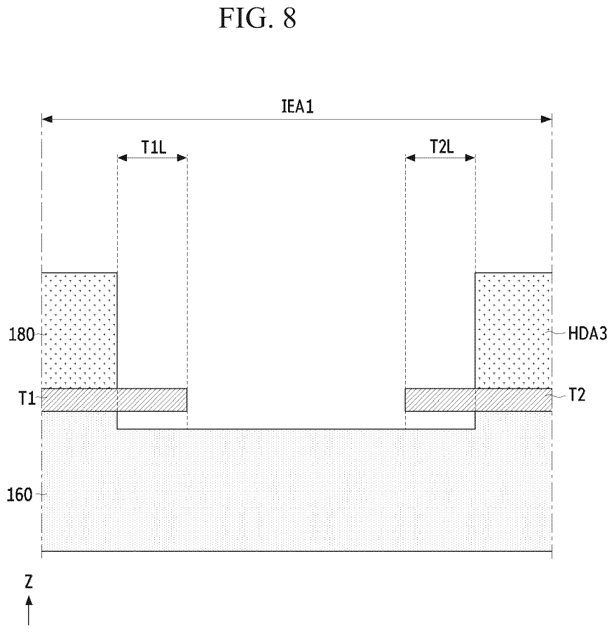

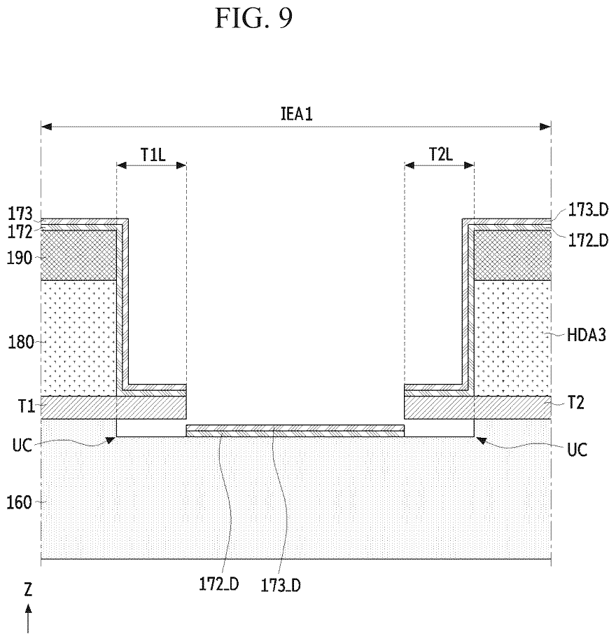

FIGS. 6 to 9 are cross-sectional views illustrating an embodiment of a process (or method) of forming a first inorganic encapsulation area.

Referring to FIG. 6, in an embodiment, a first inorganic encapsulation area IEA1 may include the first organic film 160 having an opening defined therein, the first tip T1 and the second tip T2 located on the first organic film 160, and the second organic film 180 and the third sub-dam HDA3 located on the first tip T1 and the second tip T2.

The illustrated first inorganic encapsulation area IEA1 corresponds to the first inorganic encapsulation area IEA1 of FIG. 5, but a same formation process may also be applied to a second inorganic encapsulation area IEA2, a third inorganic encapsulation area IEA3, and a fourth inorganic encapsulation area IEA4.

The first tip T1 may be located between the first organic film 160 and the second organic film 180. The second tip T2 may be located between the first organic film 160 and the third sub-dam HDA3. At least a portion of the first tip T1 may be exposed without being covered by the second organic film 180. At least a portion of the second tip T2 may be exposed without being covered by the third sub-dam HDA3.

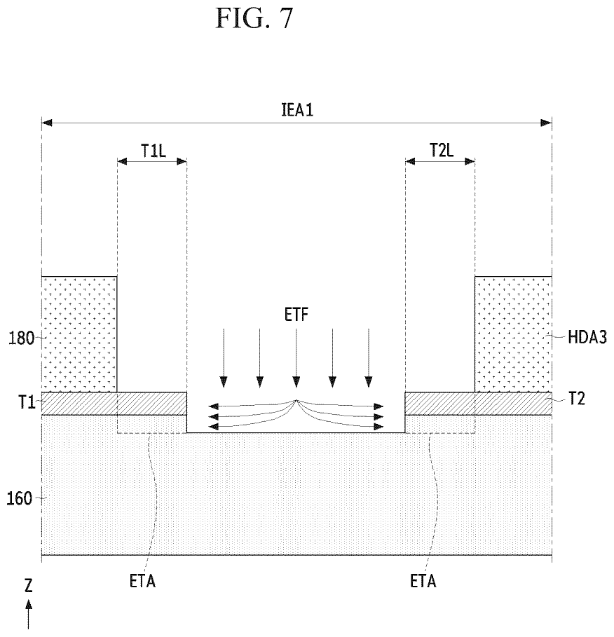

Referring to FIGS. 7, 8, and 9, in such an embodiment, an etching process may be performed. The etching process may be a wet etching process or a dry etching process. When a wet etching process is performed, an etchant ETF may be sprayed, but embodiments of the present disclosure are not limited thereto.

A preset etching area ETA may be etched by the etching process. The duration of the etching process may be adjusted based on the shape, height, size, width, or the like of the etching area ETA.

As the etching area ETA is designed, an exposure length T1L of the first tip T1 and an exposure length T2L of the second tip T2 may be determined.

The exposure length T1L of the first tip T1 may refer to the length of a portion of the bottom surface of the first tip T1 that is exposed by the first organic film 160 without overlapping the first organic film 160. The exposure length T2L of the second tip T2 may refer to the length of a portion of the bottom surface of the second tip T2 that is exposed by the first organic film 160 without overlapping the first organic film 160.

As the etching process is performed corresponding to the designed etching area ETA, a top surface of the first organic film 160, the bottom surface of the first tip T1 or the second tip T2, and one surface of the etching area ETA may form an undercut structure UC.

Subsequently, the bank 190 may be deposited on the second organic film 180, and the light emitting layer 172 and the common electrode 173 may be formed on the bank 190. In an embodiment, the light emitting layer 172 may be disconnected by the undercut structure UC formed by the first tip T1 and the undercut structure UC formed by the second tip T2. In addition, the common electrode 173 may also be disconnected by the undercut structure UC formed by the first tip T1 and the undercut structure UC formed by the second tip T2. The light emitting layer 172 and the common electrode 173 that are disconnected by the undercut structure UC may become the light emitting layer remnant 172_D and the common electrode remnant 173_D, respectively. Therefore, the light emitting layer remnant 172_D may include a same material as the light emitting layer 172, and the common electrode remnant 173_D may include a same material as the common electrode 173.

The exposure length T1L of the first tip T1 and the exposure length T2L of the second tip T2 may play a major role in causing disconnection of the light emitting layer 172 and the common electrode 173. In an embodiment, for example, as the exposure length T1L of the first tip T1 or the exposure length T2L of the second tip T2 increases, the likelihood of disconnection of each of the light emitting layer 172 and the common electrode 173 may increase. As described above, the inorganic encapsulation area according to an embodiment may include a plurality of tips, and due to such a tip structure, each of the light emitting layer 172 and the common electrode 173 may be disconnected. Accordingly, each of the light emitting layer 172 and the common electrode 173 may be effectively prevented from becoming a permeation path for oxygen and/or moisture, and reliability of the display device may be improved. In this process, the exposure lengths T1L and T2L of the tips have a significant impact on whether disconnection occurs, and therefore, it is desired to accurately measure or determine the exposure lengths T1L and T2L of the tips during the manufacturing process of the display device.

Conventionally, the exposure lengths T1L and T2L of the tips have been estimated by checking the cross-sectional structure of the inorganic encapsulation area using a focused ion beam (FIB) analysis method. However, such an analysis method involves capturing an image and thus may cause an erroneous measurement. The erroneous measurement may occur because the contrast of the measured image varies depending on the formation angles of the tips T1 and T2 or the degree of ashing performed after the etching process.

Accordingly, embodiments of the present disclosure provide a display device capable of measuring or determining the exposure lengths T1L and T2L of the tips. An embodiment may include a test area TEA including a metal pattern MPT, and the accuracy of measuring the exposure lengths T1L and T2L of the tips may be improved based on the shape or configuration of the metal pattern MPT present in the test area TEA. According to an embodiment, since the accuracy of measuring the exposure lengths T1L and T2L of the tips is improved, the accuracy of determining whether the light emitting layer 172 or the like is disconnected may be enhanced. Accordingly, the light emitting layer 172 and the like may be effectively prevented from becoming permeation paths for moisture or the like, and thus reliability of the display device may be improved.

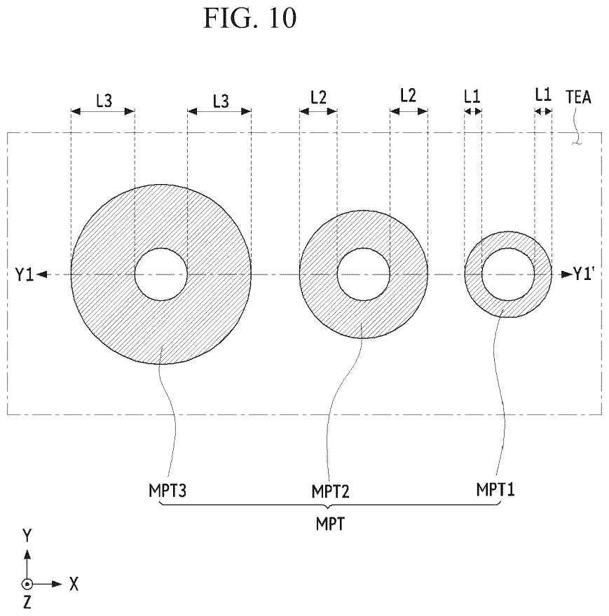

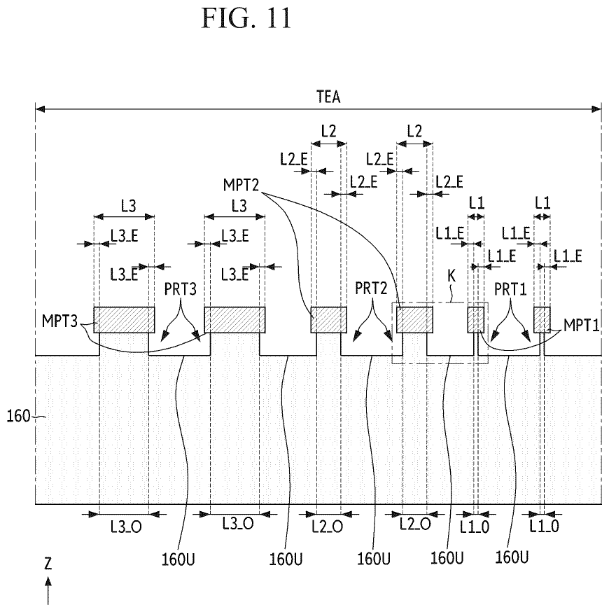

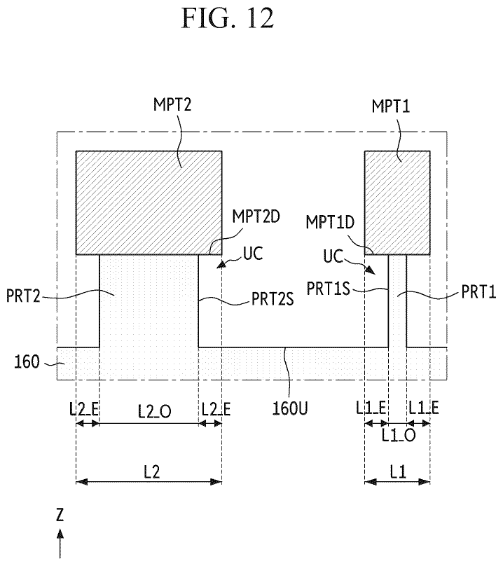

FIG. 10 is a plan view illustrating a test area according to an embodiment of the present disclosure. FIG. 11 is a cross-sectional view illustrating a portion taken along line Y1-Y1′ of FIG. 10. FIG. 12 is a partially enlarged view of area K of FIG. 11. FIG. 10 may be a partially enlarged view showing area J of FIG. 1.

Referring to FIG. 10, the display device according to an embodiment may include the test area TEA. The test area TEA may be located in the display area or in the non-display area. The test area TEA may be provided to improve the accuracy of measuring the exposure length of the tip formed in the inorganic encapsulation area. Accordingly, the test area TEA may be located in the display area or the non-display area (e.g., area J of FIG. 1) relatively adjacent to the through hole.

The test area TEA may include the metal pattern MPT. The metal pattern MPT may include a plurality of metal pattern portions that are independently present from each other. The metal pattern MPT may include a first metal pattern portion MPT1, a second metal pattern portion MPT2, and a third metal pattern portion MPT3, but embodiments of the present disclosure are not limited thereto. The first metal pattern portion MPT1, the second metal pattern portion MPT2, and the third metal pattern portion MPT3 may be located to be spaced apart from each other in a first direction (e.g., an X-axis direction), but embodiments of the present disclosure are not limited thereto.

Each of the first metal pattern portion MPT1, the second metal pattern portion MPT2, and the third metal pattern portion MPT3 may have a length in the first direction (e.g., the X-axis direction). The first metal pattern portion MPT1 may have a first length L1 in the first direction (e.g., the X-axis direction), the second metal pattern portion MPT2 may have a second length L2 in the first direction (e.g., the X-axis direction), and the third metal pattern portion MPT3 may have a third length L3 in the first direction (e.g., the X-axis direction). The length in the first direction (e.g., the X-axis direction) may also be referred to as a width of each metal pattern portion. In an embodiment, as shown in FIG. 10, each of the first metal pattern portion MPT1, the second metal pattern portion MPT2, and the third metal pattern portion MPT3 may be formed in a ring shape, and the widths of the rings may correspond to the first length L1, the second length L2, and the third length L3, respectively.

In an embodiment, the first length L1, the second length L2, and the third length L3 may differ from each other. In an embodiment, for example, the first length L1 may be smaller than the second length L2, and the second length L2 may be smaller than the third length L3.

In an embodiment, the metal pattern MPT may be in a circular shape, a donut shape, or a ring shape, but embodiments of the present disclosure are not limited thereto. As in another embodiment to be described later, where a plurality of metal pattern portions having different lengths in the first direction (e.g., the X-axis direction) are included, each metal pattern portion may have a polygonal shape. In addition, although the plurality of metal pattern portions are independently present, the plurality of metal pattern portions may share a center of mass or a center of a circle, as in a modified example to be described later. In an embodiment where the metal pattern MPT includes metal pattern portions having different lengths in the first direction (e.g., the X-axis direction), the specific shape of the metal pattern MPT is not limited to the illustrated examples.

Referring to FIG. 11, the metal pattern MPT included in the test area TEA may be formed to include a same material as the tip. Therefore, the metal pattern MPT may be located on the first organic film 160, similarly to the tip. The metal pattern MPT may be included in the second data metal layer located on the first organic film 160. The second data metal layer may include the plurality of metal pattern portions included in the test area TEA.

The plurality of metal pattern portions may have different lengths in the first direction (e.g., the X-axis direction). The first metal pattern portion MPT1 may have the first length L1 in the first direction (e.g., the X-axis direction), the second metal pattern portion MPT2 may have the second length L2 in the first direction (e.g., the X-axis direction), and the third metal pattern portion MPT3 may have the third length L3 in the first direction (e.g., the X-axis direction).

The first organic film 160 may include a first protrusion PRT1, a second protrusion PRT2, and a third protrusion PRT3. Each of the first protrusion PRT1, the second protrusion PRT2, and the third protrusion PRT3 may have a shape protruding toward the top of the display device while being physically connected to the first organic film 160.

The first metal pattern portion MPT1 may be located on the first protrusion PRT1. At least a partial region of a bottom surface MPT1D of the first metal pattern portion MPT1 may be located to be in contact with the first protrusion PRT1. At least a partial region of the bottom surface MPT1D of the first metal pattern portion MPT1 may overlap the first protrusion PRT1 in the third direction (e.g., the Z-axis direction or a thickness direction), and the remaining region thereof may be located to be offset from the first protrusion PRT1 without overlapping it in the third direction (e.g., the Z-axis direction or the thickness direction). The remaining region may be exposed without being covered by the first protrusion PRT1.

The first length L1 may be defined as the sum of a first overlapping length L1_O and a first exposure length L1_E. The first overlapping length L1_O may be defined as a length in the first direction (e.g., the X-axis direction) of a region that overlaps (or contacts) the first protrusion PRT1 of the first organic film 160 in the third direction (e.g., the Z-axis direction or the thickness direction). The first exposure length L1_E may be defined as a length in the first direction (e.g., the X-axis direction) of a region that is offset from the first protrusion PRT1 of the first organic film 160 without overlapping the first protrusion PRT1 in the third direction (e.g., the Z-axis direction or the thickness direction). The sum of the first overlapping length L1_O and the first exposure length L1_E may be the first length L1, but embodiments of the present disclosure are not limited thereto.

The second metal pattern portion MPT2 may be located on the second protrusion PRT2. At least a partial region of a bottom surface MPT2D of the second metal pattern portion MPT2 may be located to be in contact with the second protrusion PRT2. At least a partial region of the bottom surface MPT2D of the second metal pattern portion MPT2 may overlap the second protrusion PRT2 in the third direction (e.g., the Z-axis direction or the thickness direction), and the remaining region thereof may be located to be offset from the second protrusion PRT2 without overlapping the second protrusion PRT2 in the third direction (e.g., the Z-axis direction or the thickness direction). The remaining region may be exposed without being covered by the second protrusion PRT2.

The second length L2 may be defined as the sum of a second overlapping length L2_O and a second exposure length L2_E. The second overlapping length L2_O may be defined as a length in the first direction (e.g., the X-axis direction) of a region that overlaps the second protrusion PRT2 of the first organic film 160 in the third direction (e.g., the Z-axis direction or the thickness direction). The second exposure length L2_E may be defined as a length in the first direction (e.g., X-axis direction) of a region that is offset from the second protrusion PRT2 of the first organic film 160 without overlapping the second protrusion PRT2 in the third direction (e.g., the Z-axis direction or the thickness direction). The sum of the second overlapping length L2_O and the second exposure length L2_E may be the second length L2, but embodiments of the present disclosure are not limited thereto.

The third metal pattern portion MPT3 may be located on the third protrusion PRT3. At least a partial region of the bottom surface of the third metal pattern portion MPT3 may be located to be in contact with the third protrusion PRT3. At least a partial region of the bottom surface of the third metal pattern portion MPT3 may overlap the third protrusion PRT3 in the third direction (e.g., the Z-axis direction or the thickness direction), and the remaining region thereof may be located to be offset from the third protrusion PRT3 without overlapping the third protrusion PRT3 in the third direction (e.g., the Z-axis direction or the thickness direction). The remaining region may be exposed without being covered by the third protrusion PRT3.

The third length L3 may be defined as the sum of a third overlapping length L3_O and a third exposure length L3_E. The third overlapping length L3_O may be defined as a length in the first direction (e.g., the X-axis direction) of a region that overlaps the third protrusion PRT3 of the first organic film 160 in the third direction (e.g., the Z-axis direction or the thickness direction). The third exposure length L3_E may be defined as a length in the first direction (e.g., the X-axis direction) of a region that is offset from the third protrusion PRT3 of the first organic film 160 without overlapping the third protrusion PRT3 in the third direction (e.g., the Z-axis direction or the thickness direction). The sum of the third overlapping length L3_O and the third exposure length L3_E may be the third length L3, but embodiments of the present disclosure are not limited thereto.

In an embodiment, the exposure length of each of the plurality of metal pattern portions may have been formed together when an etching process was performed on the tip. The execution time of the etching process or the like may be applied equally to all of the plurality of metal pattern portions, and furthermore, may also be applied equally to the inorganic encapsulation area. In such an embodiment, the first exposure length L1_E, the second exposure length L2_E, and the third exposure length L3_E may all be the same as each other, but embodiments of the present disclosure are not limited thereto. In consideration of a process error or the like, the first exposure length L1_E, the second exposure length L2_E, and the third exposure length L3_E may be substantially the same as each other. Since the third length L3 is greater than the second length L2 and the second length L2 is greater than the first length L1, the third overlapping length L3_O may be greater than the second overlapping length L2_O, and the second overlapping length L2_O may be greater than the first overlapping length L1_O.

Referring to FIG. 12, similarly to the undercut structure UC formed by the tip of the inorganic encapsulation area, the undercut structure UC may also be formed in the test area TEA.

The bottom surface MPT1D of the first metal pattern portion MPT1, one side surface PRT1S of the first protrusion PRT1, and the top surface 160U of the first organic film 160 may form the undercut structure UC. One side surface PRT1S of the first protrusion PRT1 and a portion of the bottom surface MPT1D of the first metal pattern portion MPT1 that is exposed by the first protrusion PRT1 without being in contact with the first protrusion PRT1 may form the undercut structure UC.

The bottom surface MPT2D of the second metal pattern portion MPT2, one side surface PRT2S of the second protrusion PRT2, and the top surface 160U of the first organic film 160 may form the undercut structure UC. One side surface PRT2S of the second protrusion PRT2 and a portion of the bottom surface MPT2D of the second metal pattern portion MPT2 that is exposed by the second protrusion PRT2 without being in contact with the second protrusion PRT2 may form the undercut structure UC.

The first exposure length L1_E and the second exposure length L2_E may be substantially the same as each other, as described above. A process for forming them to be equal will be described later. Since the second length L2 is greater than the first length L1, the second overlapping length L2_O may be greater than the first overlapping length L1_O.

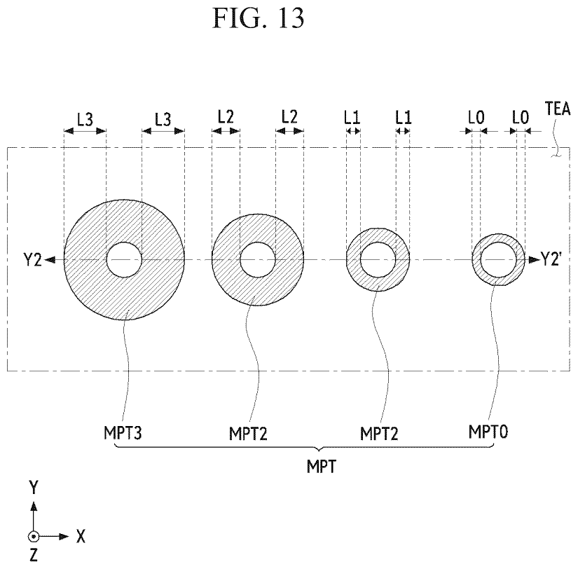

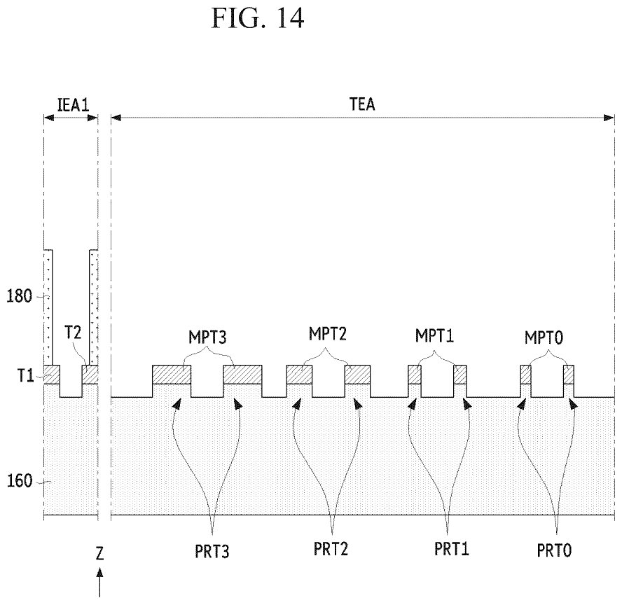

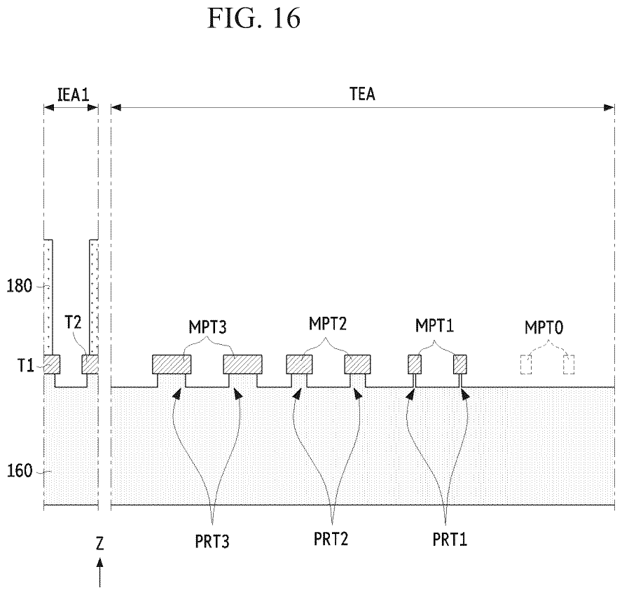

FIG. 13 is a plan view illustrating a process of forming a test area of FIG. 10 according to an embodiment of the present disclosure. FIGS. 14 to 16 are cross-sectional views illustrating a process of forming a test area of FIG. 10 according to an embodiment of the present disclosure. These are also cross-sectional views corresponding to a portion taken along line Y2-Y2′ of FIG. 13.

Referring to FIG. 13, the metal pattern MPT located in the test area TEA may further include a missing metal pattern portion MPT0 in addition to the first metal pattern portion MPT1, the second metal pattern portion MPT2, and the third metal pattern portion MPT3. As its designation implies, the missing metal pattern portion MPT0 is a metal pattern portion that disappears from the test area TEA at a later stage during the manufacturing process and, therefore, may not be present in the final product of the display device according to an embodiment. The missing metal pattern portion MPT0 may have a fourth length L0 in the first direction (e.g., the X-axis direction). The number of metal pattern portions included in the metal pattern MPT that is initially formed may be greater than the number of metal pattern portions remaining after a tip exposure length test.

In an embodiment, a difference between the number of metal pattern portions included in the initially formed metal pattern MPT and the number of metal pattern portions remaining after the tip exposure length test may be one or two or greater. As shown in the drawings, although the difference is one, the number of metal pattern portions may be increased to improve the measurement accuracy of the tip exposure length test. As the number of metal pattern portions having different lengths increases, the accuracy of the tip exposure length measurement may also be improved.

For the simplicity of description, it is assumed that the first length L1 is smaller than the second length L2, the second length L2 is smaller than the third length L3, and the fourth length L0 is smaller than the first length L1. After the etching process is performed, the missing metal pattern portion MPT0 having the fourth length L0, which corresponds to approximately twice the tip exposure length, may be removed or disappear in a subsequent process, as will be described later. Alternatively, another missing metal pattern portion MPT0 or other missing metal pattern portions MPT0 having a length smaller than approximately twice the tip exposure length may be removed or disappear in a subsequent process, as will be described later.

Referring to FIG. 14, the etching process performed on the first inorganic encapsulation area IEA1 may be applied equally to the metal pattern MPT located in the test area TEA. The first organic film 160 located in the test area TEA may include the first protrusion PRT1, the second protrusion PRT2, the third protrusion PRT3, a fourth protrusion PRT0, and an opening may be formed or defined by these protrusions. Similarly, the first organic film 160 located in the first inorganic encapsulation area IEA1 may also have an opening defined therein, but embodiments of the present disclosure are not limited thereto.

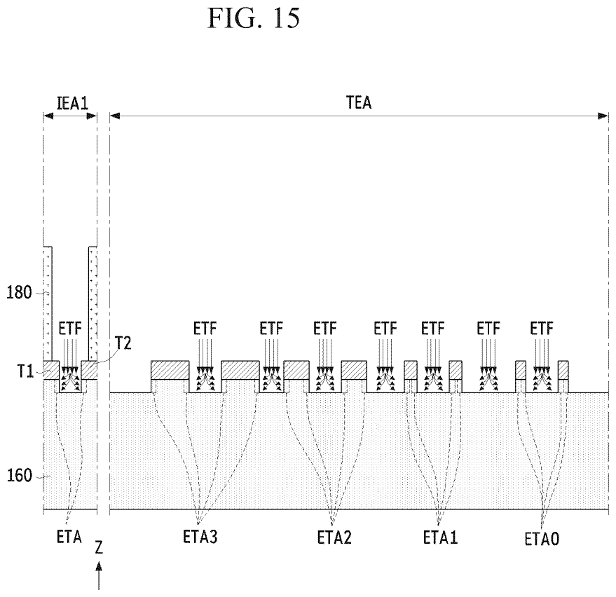

Referring to FIG. 15, an etching process may be performed on both the first inorganic encapsulation area IEA1 and the test area TEA. In an embodiment, for example, the etching area ETA of the first organic film 160 may be etched as the etchant ETF is sprayed.

The etching area ETA may have a predesigned shape, width, size, height, thickness, and the like, and may also be formed in the test area TEA in addition to the first inorganic encapsulation area IEA1. Since a same etching process is performed in the test area TEA and the first inorganic encapsulation area IEA1, the duration of the etching process may also be a same in both areas. Therefore, the shape, size, and the like of the etching area ETA may be the same in the first inorganic encapsulation area IEA1 and the test area TEA.

A fourth etching area ETA0 formed in the missing metal pattern portion MPT0, a first etching area ETA1 formed in the first metal pattern portion MPT1, a second etching area ETA2 formed in the second metal pattern portion MPT2, a third etching area ETA3 formed in the third metal pattern portion MPT3, and the etching area ETA formed in the first inorganic encapsulation area IEA1 may be designed to have substantially the same size, shape, and the like as each other. The length of the etching area ETA in the first direction (e.g., the X-axis direction) may correspond to the exposure lengths of the tips T1 and T2.

Referring to FIGS. 13 to 16, the missing metal pattern portion MPT0 may have the fourth length L0, and the fourth length L0 may correspond to approximately twice the length of the etching area ETA in the first direction (e.g., the X-axis direction), or may be smaller than that.

As shown in the above-described drawings, etching may be performed on both opposing side surfaces of the fourth protrusion PRT0 that supports the missing metal pattern portion MPT0. After etching is performed for the execution time of the etching process corresponding to the designed etching area ETA, the fourth protrusion PRT4 supporting the missing metal pattern portion MPT0 may be completely removed.

Among the metal pattern portions included in the initially formed metal pattern MPT, a metal pattern portion having a length of approximately twice the tip exposure length or less may be removed due to the absence of a protrusion therebelow to support after the etching process is performed.

In other words, the number of metal pattern portions included in the initially formed metal pattern MPT may differ from the number of metal pattern portions remaining after the tip exposure length test. The practitioner may improve the accuracy of the tip exposure length measurement by increasing the number of metal pattern portions in the process of initially designing the metal pattern portions.

If the lengths of the metal pattern portions in the initially formed metal pattern MPT were 2, 4, 6, and 8 (no unit; A.U.), and the lengths of the metal pattern portions remaining after the tip exposure length test are 4, 6, and 8, the tip exposure length would be less than 2. In other words, the tip exposure length can be inferred to be less than half of the minimum value of the lengths of the remaining metal pattern portions in the first direction (e.g., the X-axis direction).

If the lengths of the metal pattern portions in the initially formed metal pattern MPT were k, k+m, k+l, . . . (where m is a positive real number greater than 0, and l is a positive real number greater than m), and the minimum value of the lengths of the metal pattern portions remaining after the tip exposure length test is k+m, it can be inferred that the tip exposure length is less than (k+m)/2. If the tip exposure length were equal to (k+m)/2, the metal pattern portion having the length of k+m would have been removed, and therefore, the tip exposure length cannot be equal to (k+m)/2.

Referring back to the drawings, the display device according to an embodiment may include the first metal pattern portion MPT1 and the second metal pattern portion MPT2 having the first length L1 and the second length L2, respectively, which differ from each other. The missing metal pattern portion MPT0 does not remain, and the first length L1 differs from the second length L2. In a case where the first length L1 is smaller than the second length L2, it can be inferred that the tip exposure length is less than half of the first length L1.

In the display device according to an embodiment, the accuracy of the tip exposure length measurement may be improved. The tip exposure length may be measured based on the length in a specific direction of the metal pattern portions remaining in the test area TEA, and the tip exposure length may be inferred without performing a separate cross-sectional image analysis. As the number of metal pattern portions included in the metal pattern MPT increases, and the length difference between the shortest metal pattern portion among the remaining metal pattern portions and the longest metal pattern portion among the missing metal pattern portions MPT0 becomes finer, the accuracy of measurement of the tip exposure length may be improved.

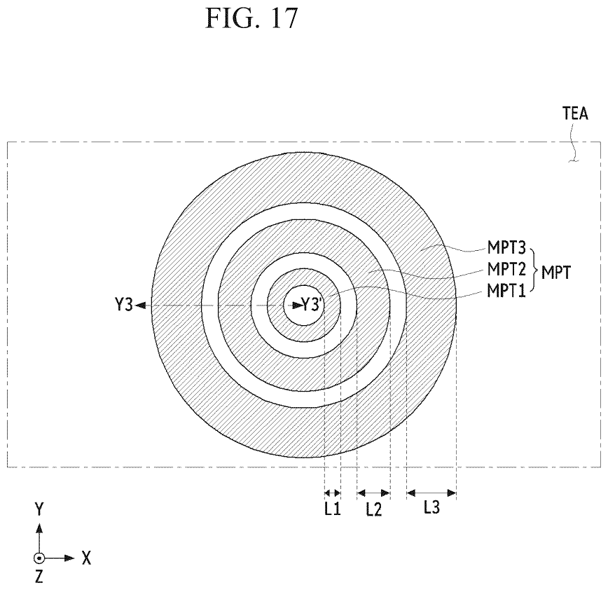

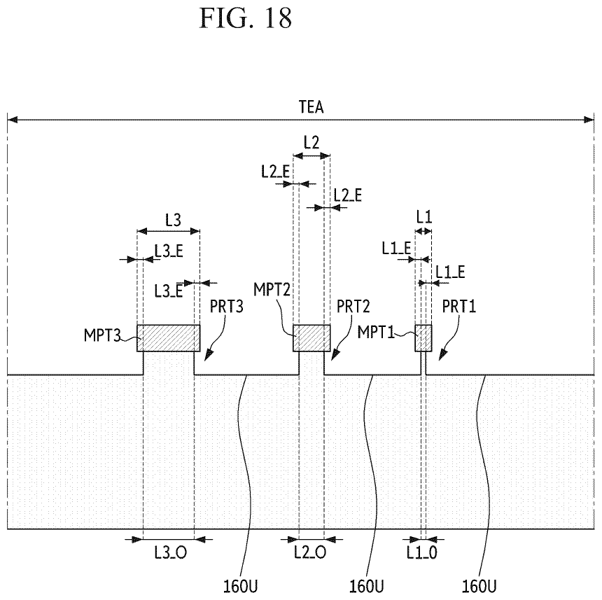

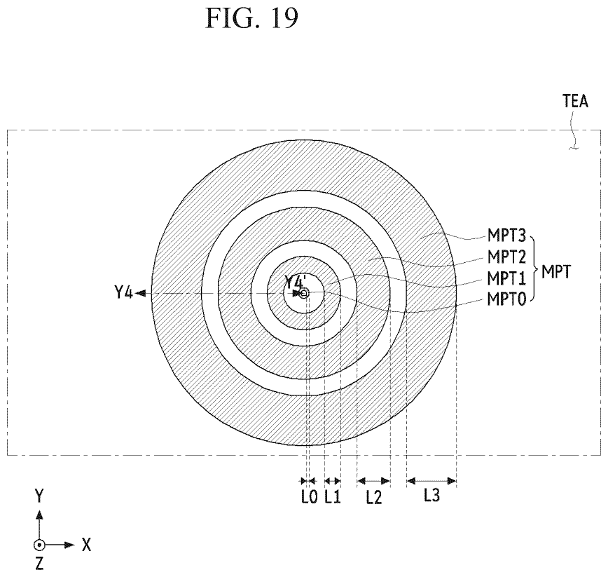

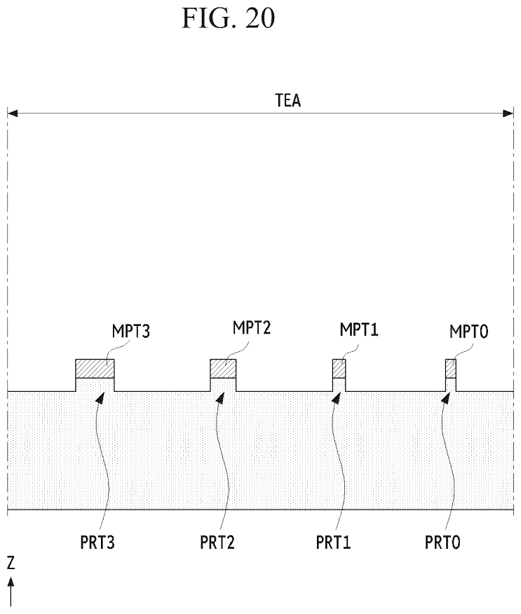

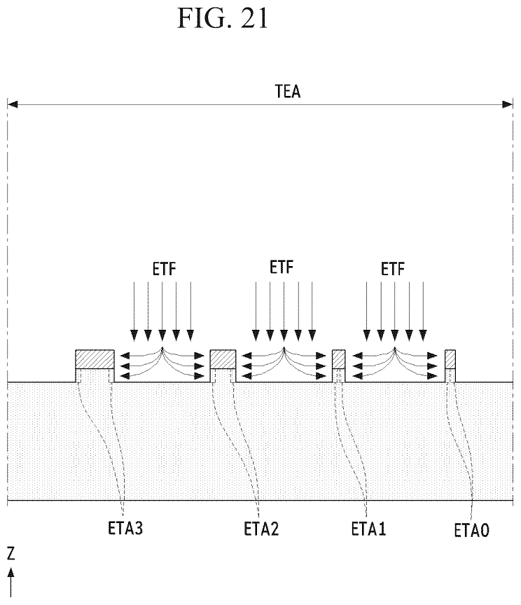

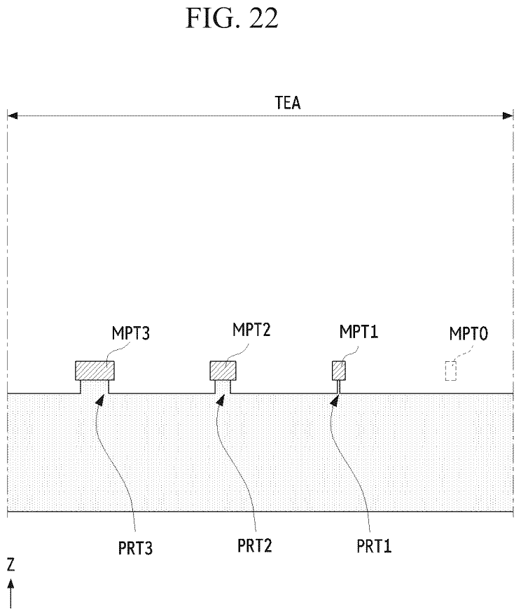

FIG. 17 is a plan view showing a modified example of FIG. 10. FIG. 18 is a cross-sectional view illustrating a portion taken along line Y3-Y3′ of FIG. 17. FIG. 19 is a plan view illustrating a process of forming a test area according to the modified example of FIG. 10. FIGS. 20 to 22 are cross-sectional views illustrating a process of forming a test area according to the modified example of FIG. 10. These are also cross-sectional views corresponding to a portion taken along line Y4-Y4′ of FIG. 19.

Referring to FIGS. 17 to 22, in embodiments of the present disclosure, design shapes between the plurality of metal pattern portions arranged in the test area TEA may be variously modified. In an embodiment, as described above, for example, the plurality of metal pattern portions formed in a circular shape, a donut shape, or a ring shape were arranged such that their centers of mass are spaced apart from each other. In another embodiment, as shown in FIG. 17, the centers of mass of the plurality of metal pattern portions may overlap each other in the third direction (e.g., the Z-axis direction or the thickness direction).

In such an embodiment, the metal pattern MPT may include the first metal pattern portion MPT1 having the first length L1 in the first direction (e.g., the X-axis direction), the second metal pattern portion MPT2 having the second length L2 in the first direction (e.g., the X-axis direction), and the third metal pattern portion MPT3 having the third length L3 in the first direction (e.g., the X-axis direction). In an embodiment, where the first length L1 is the smallest, the tip exposure length may be less than half of the smallest first length L1 among the lengths in the first direction (e.g., the X-axis direction) of the remaining metal pattern portions located in the test area TEA.

Although the designed positional relationship of the plurality of metal pattern portions may be variously modified, the remaining metal pattern portions may have different lengths in the first direction (e.g., the X-axis direction).

A metal pattern portion having a value less than approximately twice the tip exposure length may become missing due to the absence of a protrusion supporting the metal pattern portion. For this reason, in the display device according to the embodiment of FIG. 10 or the modified example thereof, the tip exposure length may be inferred from the smallest value among the lengths of the remaining metal pattern portions in the first direction (e.g., the X-axis direction).

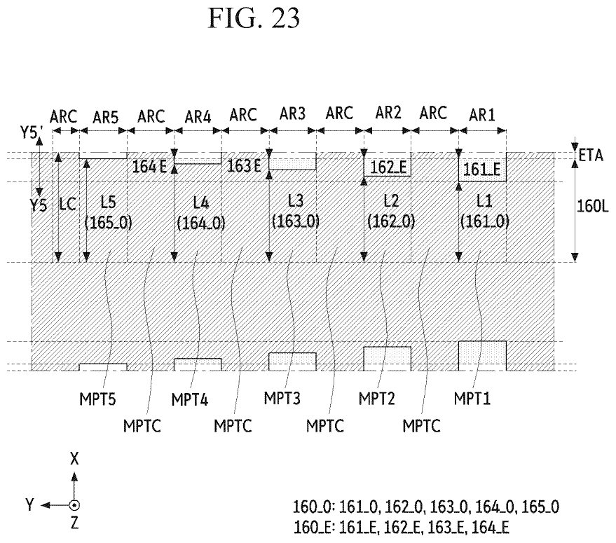

FIG. 23 is a plan view illustrating a test area according to another embodiment of the present disclosure.

Referring to FIG. 23, the test area TEA according to an embodiment may include the metal pattern MPT including a plurality of metal pattern portions physically connected to each other. The metal pattern MPT may include a first metal pattern portion MPT1, a second metal pattern portion MPT2, a third metal pattern portion MPT3, a fourth metal pattern portion MPT4, a fifth metal pattern portion MPT5, and a reference metal pattern portion MPTC. The test areas TEA according to embodiments described above may both include a plurality of metal pattern portions having different lengths from each other. The first metal pattern portion MPT1 may have a first length L1 in the first direction (e.g., the X-axis direction), the second metal pattern portion MPT2 may have a second length L2 in the first direction (e.g., the X-axis direction), the third metal pattern portion MPT3 may have a third length L3 in the first direction (e.g., the X-axis direction), the fourth metal pattern portion MPT4 may have a fourth length L4 in the first direction (e.g., the X-axis direction), the fifth metal pattern portion MPT5 may have a fifth length L5 in the first direction (e.g., the X-axis direction). Although only up to the fifth metal pattern portion MPT5 is illustrated in FIG. 23 as an example, similarly to the embodiment of FIG. 10, as the number of metal pattern portions increases, the accuracy of the tip exposure length measurement may be improved. The reference metal pattern portion MPTC may have a reference length LC.

In such an embodiment, the reference metal pattern portion MPTC having the reference length LC in the first direction (e.g., the X-axis direction) may be located between the plurality of metal pattern portions. The reference metal pattern portion MPTC may be located between the first metal pattern portion MPT1, the second metal pattern portion MPT2, the third metal pattern portion MPT3, the fourth metal pattern portion MPT4, and the fifth metal pattern portion MPT5 to be physically connected to each of them.

In an embodiment, a first region AR1 including the first metal pattern portion MPT1, a second region AR2 including the second metal pattern portion MPT2, a third region AR3 including the third metal pattern portion MPT3, a fourth region AR4 including the fourth metal pattern portion MPT4, and a fifth region AR5 including the fifth metal pattern portion MPT5 may be defined. In addition, in an embodiment, a reference area ARC including the reference metal pattern portion MPTC may be defined.

In an embodiment, the first length L1 may be smaller than the second length L2, the second length L2 may be smaller than the third length L3, the third length L3 may be smaller than the fourth length L4, and the fourth length L4 may be smaller than the fifth length L5.

Each of the metal pattern portions may be located on the first organic film 160. In the display device according to the embodiment of FIG. 23, the first organic film 160 may have a sixth length 160L in the first direction (e.g., the X-axis direction). In addition, the sum of the sixth length 160L and the length of the etching area ETA in the first direction (e.g., the X-axis direction) may be substantially equal to the reference length LC.

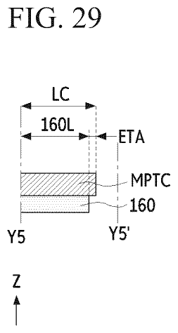

In the reference area ARC including the reference metal pattern portion MPTC, at least a portion of the reference metal pattern portion MPTC may overlap the first organic film 160 in the third direction (e.g., the Z-axis direction or the thickness direction). As described in a cross-sectional view to be described later, at least a portion of the bottom surface of the reference metal pattern portion MPTC may be exposed by the first organic film 160 (see FIG. 29).

At least a portion of the first organic film 160 located in the first region AR1 may overlap the first metal pattern portion MPT1 in the third direction (e.g., the Z-axis direction or the thickness direction). The remaining portion of the first organic film 160 located in the first region AR1 may be offset from the first metal pattern portion MPT1 without overlapping the first metal pattern portion MPT1 in the third direction (e.g., the Z-axis direction or the thickness direction). In other words, the remaining portion of the first organic film 160 located in the first region AR1 may be exposed by the first metal pattern portion MPT1. The first organic film 160 that overlaps the first metal pattern portion MPT1 in the third direction (e.g., the Z-axis direction or the thickness direction) may have a first overlapping length 161_O. The first organic film 160 located to be offset from the first metal pattern portion MPT1 without overlapping the first metal pattern portion MPT1 in the third direction (e.g., the Z-axis direction or the thickness direction) may have a first exposure length 161_E. In an embodiment, the sum of the first overlapping length 161_O and the first exposure length 161_E may be equal to the sixth length 160L.

At least a portion of the first organic film 160 located in the second region AR2 may overlap the second metal pattern portion MPT2 in the third direction (e.g., the Z-axis direction or the thickness direction). The remaining portion of the first organic film 160 located in the second region AR2 may be offset from the second metal pattern portion MPT2 without overlapping the second metal pattern portion MPT2 in the third direction (e.g., the Z-axis direction or the thickness direction). In other words, the remaining portion of the first organic film 160 located in the second region AR2 may be exposed by the second metal pattern portion MPT2. The first organic film 160 that overlaps the second metal pattern portion MPT2 in the third direction (e.g., the Z-axis direction or the thickness direction) may have a second overlapping length 162_O. The first organic film 160 located to be offset from the second metal pattern portion MPT2 without overlapping the second metal pattern portion MPT2 in the third direction (e.g., the Z-axis direction or the thickness direction) may have a second exposure length 162_E. In an embodiment, the sum of the second overlapping length 162_O and the second exposure length 162_E may be equal to the sixth length 160L.

At least a portion of the first organic film 160 located in the third region AR3 may overlap the third metal pattern portion MPT3 in the third direction (e.g., the Z-axis direction or the thickness direction). The remaining portion of the first organic film 160 located in the third region AR3 may be offset from the third metal pattern portion MPT3 without overlapping the third metal pattern portion MPT3 in the third direction (e.g., the Z-axis direction or the thickness direction). In other words, the remaining portion of the first organic film 160 located in the third region AR3 may be exposed by the third metal pattern portion MPT3. The first organic film 160 that overlaps the third metal pattern portion MPT3 in the third direction (e.g., the Z-axis direction or the thickness direction) may have a third overlapping length 163_O. The first organic film 160 located to be offset from the third metal pattern portion MPT3 without overlapping the third metal pattern portion MPT3 in the third direction (e.g., the Z-axis direction or the thickness direction) may have a third exposure length 163_E. In an embodiment, the sum of the third overlapping length 163_O and the third exposure length 163_E may be equal to the sixth length 160L.

At least a portion of the first organic film 160 located in the fourth region AR4 may overlap the fourth metal pattern portion MPT4 in the third direction (e.g., the Z-axis direction or the thickness direction). The remaining portion of the first organic film 160 located in the fourth region AR4 may be offset from the fourth metal pattern portion MPT4 without overlapping the fourth metal pattern portion MPT4 in the third direction (e.g., the Z-axis direction or the thickness direction). In other words, the remaining portion of the first organic film 160 located in the fourth region AR4 may be exposed by the fourth metal pattern portion MPT4. The first organic film 160 that overlaps the fourth metal pattern portion MPT4 in the third direction (e.g., the Z-axis direction or the thickness direction) may have a fourth overlapping length 164_O. The first organic film 160 located to be offset from the fourth metal pattern portion MPT4 without overlapping the fourth metal pattern portion MPT4 in the third direction (e.g., the Z-axis direction or the thickness direction) may have a fourth exposure length 164_E. In an embodiment, the sum of the fourth overlapping length 164_O and the fourth exposure length 164_E may be equal to the sixth length 160L.

At least a portion of the first organic film 160 located in the fifth region AR5 may overlap the fifth metal pattern portion MPT5 in the third direction (e.g., the Z-axis direction or the thickness direction). The remaining portion of the first organic film 160 located in the fifth region AR5 may be offset from the fifth metal pattern portion MPT5 without overlapping the fifth metal pattern portion MPT5 in the third direction (e.g., the Z-axis direction or the thickness direction). In other words, the remaining portion of the first organic film 160 located in the fifth region AR5 may be exposed by the fifth metal pattern portion MPT5. The first organic film 160 that overlaps the fifth metal pattern portion MPT5 in the third direction (e.g., the Z-axis direction or the thickness direction) may have a fifth overlapping length 165_O. In an embodiment, the fifth overlapping length 165_O may be substantially equal to the sixth length 160L.

In an embodiment, an overlapping length 160_O may be defined, from the perspective of the first organic film 160, as the overlapping length of the first organic film 160 that overlaps the corresponding metal pattern portion, and an exposure length 160_E may be defined, from the perspective of the first organic film 160, as the exposure length of the first organic film 160 that is exposed by the corresponding metal pattern portion without overlapping it. Accordingly, the first length L1 may be substantially equal to the first overlapping length 161_O, the second length L2 may be substantially equal to the second overlapping length 162_O, the third length L3 may be substantially equal to the third overlapping length 163_O, the fourth length L4 may be substantially equal to the fourth overlapping length 164_O, and the fifth length L5 may be substantially equal to the fifth overlapping length 165_O. The first overlapping length 161_O, the second overlapping length 162_O, the third overlapping length 163_O, the fourth overlapping length 164_O, and the fifth overlapping length 165_O may differ from each other. In an embodiment, for example, the first overlapping length 161_O may be smaller than the second overlapping length 162_O, the second overlapping length 162_O may be smaller than the third overlapping length 163_O, the third overlapping length 163_O may be smaller than the fourth overlapping length 164_O, and the fourth overlapping length 164_O may be smaller than the fifth overlapping length 165_O.

Since the value obtained by subtracting the overlapping length 160_O from the sixth length 160L in each region including the metal pattern portion is defined as the exposure length 160_E, the first exposure length 161_E, the second exposure length 162_E, the third exposure length 163_E, and the fourth exposure length 164_E may differ from each other. In an embodiment, for example, the first exposure length 161_E may be greater than the second exposure length 162_E, the second exposure length 162_E may be greater than the third exposure length 163_E, and the third exposure length 163_E may be greater than the fourth exposure length 164_E.

The display device according to an embodiment is formed or configured in a way such that the length of the etching area ETA in the first direction (e.g., the X-axis direction), which is equal to the tip exposure length, can be visually measured. In the first to fifth regions AR1 to AR5, the metal pattern portions may be formed to have different lengths from each other. Since the first organic film 160 is removed by the length of the etching area ETA, the length of the etching area ETA may be inferred from the fifth region AR5 in which the first organic film 160 is not present when observed in plan view. The exposed first organic film 160 is present in the first to fourth regions AR1 to AR4, and the ends thereof may coincide in all regions. The tip exposure length may be inferred from the length difference in the first direction (e.g., the X-axis direction) between the end of the first organic film 160 and the end of the reference metal pattern portion MPTC.

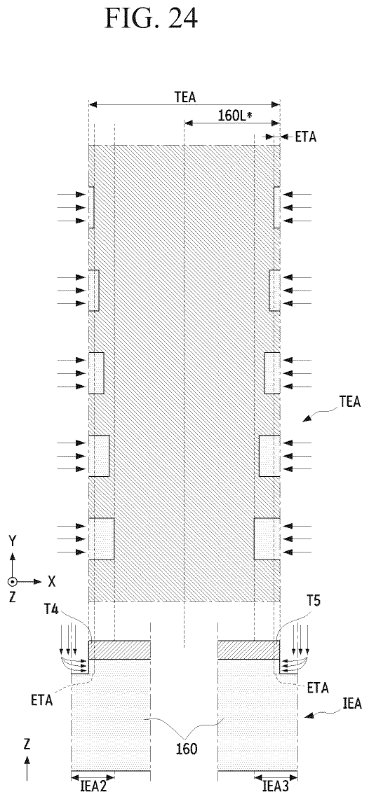

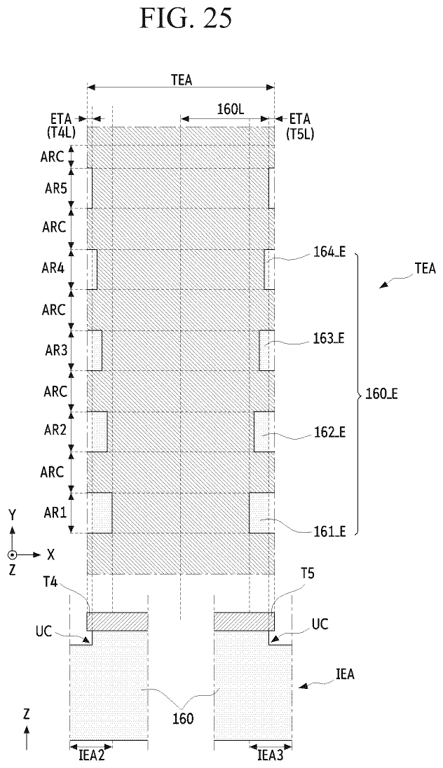

FIGS. 24 and 25 each include a plan view and a cross-sectional view illustrating a process of forming a test area of FIG. 23 according to an embodiment of the present disclosure.

Referring to FIG. 24, the first organic film 160 located in the test area TEA may have a seventh length 160L* before being etched. The end of the first organic film 160 may have a corresponding relationship as shown in the cross-sectional view of the second inorganic encapsulation area IEA2 including the fourth tip T4 and the third inorganic encapsulation area IEA3 including the fifth tip T5. The end of the reference metal pattern portion MPTC may coincide with the end of the fourth tip T4 or the fifth tip T5.

The etching area ETA may be defined in the second inorganic encapsulation area IEA2 and the third inorganic encapsulation area IEA3, and at least a portion of the seventh length 160L* may overlap the length in the first direction (e.g., the X-axis direction) of the etching area ETA.

Referring to FIG. 25, after the etching process is performed, the undercut structure UC may be formed below the fourth tip T4 and the fifth tip T5. Since the first organic film 160 having an exposure length is not present in the fifth region AR5, it may be presumed that the first organic film 160 has been removed up to the end portion of the fifth metal pattern portion MPT5 located in the fifth region AR5. As the end of the fourth tip T4 or the fifth tip T5 corresponds to the end of the reference metal pattern portion MPTC, the length of the etching area ETA may be inferred from the length difference in the first direction (e.g., the X-axis direction) between the end of the fifth metal pattern portion MPT5 and the end of the reference metal pattern portion MPTC.

In the display device according to an embodiment, the length of the etching area ETA may be inferred from the length difference in the first direction (e.g., the X-axis direction) between the end of the metal pattern portion located in a region where the exposed first organic film 160 is not present and the end of the reference metal pattern portion MPTC. In other words, the length of the etching area ETA may be inferred from the length difference in the first direction (e.g., the X-axis direction) between the end of the metal pattern portion located in a region where the exposure length is not present and the end of the reference metal pattern portion MPTC. As the number of metal pattern portions increases, a distinction between a region where the exposure length is not present and a region where the exposure length is present may become more precise, and accordingly, the accuracy of the measurement may be improved.

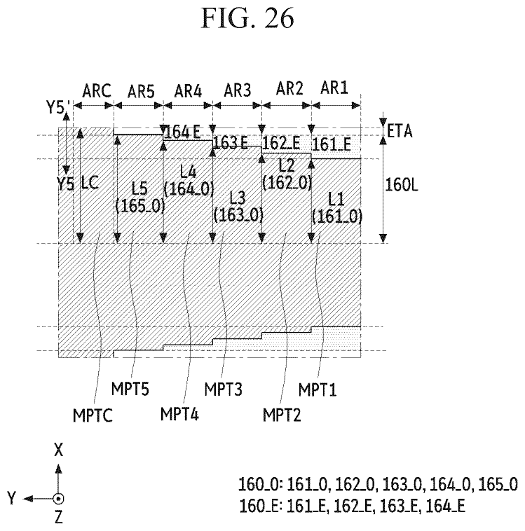

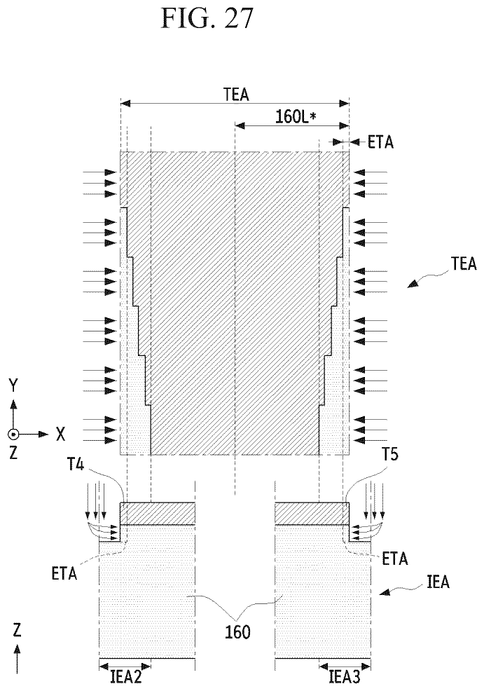

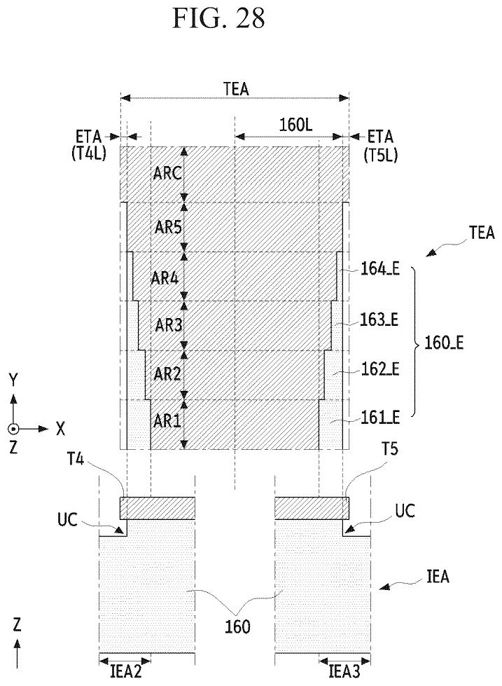

FIG. 26 is a plan view showing a modified example of FIG. 23. FIGS. 27 and 28 each include a plan view and a cross-sectional view illustrating a process of forming a test area according to the modified example of FIG. 23.

Referring to FIG. 26, the modified example is substantially the same as the embodiment of FIG. 23 except that the reference metal pattern portion MPTC is not located between the plurality of metal pattern portions. Since the end of the reference metal pattern portion MPTC corresponds to the end of the tip, the reference metal pattern portion MPTC is desired to be present. The modified example of FIG. 23 may be derived by arranging the reference metal pattern portion MPTC on one side of the metal pattern MPT and physically connecting the plurality of metal pattern portions having different lengths to each other. When the metal pattern portions in the respective regions are all connected, the metal pattern MPT may have a stepped shape.

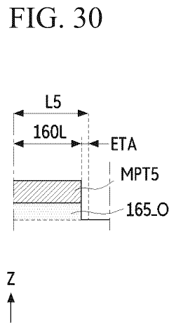

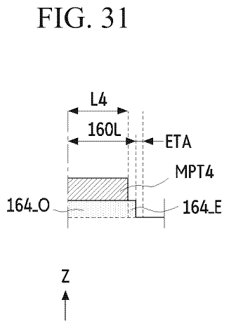

FIG. 29 is a cross-sectional view showing a reference metal pattern portion of FIG. 23 according to an embodiment of the present disclosure. FIG. 30 is a cross-sectional view showing a fifth metal pattern portion of FIG. 23 according to an embodiment of the present disclosure. FIG. 31 is a cross-sectional view showing a fourth metal pattern portion of FIG. 23 according to an embodiment of the present disclosure. FIG. 29 is also a cross-sectional view illustrating a portion taken along line Y5-Y5′ of FIGS. 23 and 26.

Referring to FIGS. 29 to 31, the undercut structure UC may be formed in the reference metal pattern portion MPTC, and a shape similar to the eaves structure of the tip may be formed. In the fifth region AR5 including the fifth metal pattern portion MPT5, only a portion corresponding to the fifth overlapping length 165_O is present, and the exposed first organic film 160 is not present. In the fourth region AR4 including the fourth metal pattern portion MPT4, at least a portion corresponding to the fourth overlapping length 164_O and the remaining portion corresponding to the fourth exposure length 164_E are present. By comparing the fifth region AR5, in which the exposed first organic film 160 is not present, with the fourth region AR4, in which the exposed first organic film 160 is present, one end of the etching area ETA may be identified from the fifth region AR5. The other end of the etching area ETA may be identified from the reference area ARC including the reference metal pattern portion MPTC. By comparing all of them, the length of the etching area ETA in the first direction (e.g., the X-axis direction) may be derived.

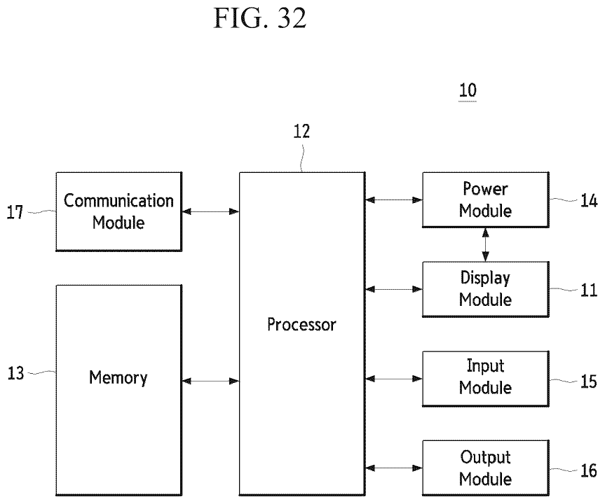

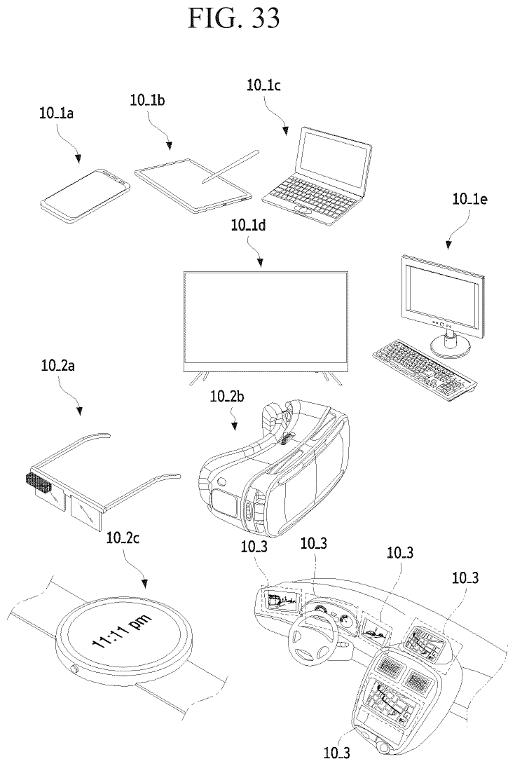

FIG. 32 is a block diagram of an electronic device according to an embodiment of the present disclosure. FIG. 33 is schematic views of electronic devices according to various embodiments of the present disclosure.

Referring to FIG. 32, an electronic device 10 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), or a controller.

The memory 13 may store data information used for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device. The power module 14 may include a power conversion module. The power conversion module may convert the power supplied by the power supply module to generate a power used for the operation of the electronic device 10.

At least one of the components of the electronic device 10 described above may be included in the display device according to the embodiments described above. Further, some of individual modules functionally included in one module may be included in the display device and some others may be provided separately from the display device. In an embodiment, for example, the display device may include the display module 11, and the processor 12, the memory 13, and the power module 14 may be provided in the form of other devices in the electronic device 10 other than the display device.

Referring to FIG. 33, various electronic devices to which the display device according to the embodiments of the present disclosure is applied may include electronic devices for displaying images, such as a smartphone 10_1a, a tablet PC 10_1b, a laptop computer 10_1c, a TV 10_1d, a desk monitor 10_1e, and the like. In addition, various electronic devices to which the display devices according to the embodiments of the present disclosure are applied may include a wearable electronic device including a display module such as smart glasses 10_2a, a head mounted display 10_2b, and a smart watch 10_2c, a vehicle electronic device 10_3 including a display module such as a center fascia, and a dashboard of an automobile, a center information display (CID) placed on the dashboard, a room mirror display, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device having a through hole defined therein, the display device comprising:
an inorganic encapsulation area located to surround the through hole and comprising a plurality of tips arranged on a first organic film; and
a test area comprising a metal pattern,
wherein the metal pattern includes a same material as the tips, and
the metal pattern comprises:
a first metal pattern portion having a first length in a first direction; and
a second metal pattern portion having a second length in the first direction, and
wherein the first length is different from the second length.

2. The display device of claim 1, wherein the metal pattern is located on the first organic film.

3. The display device of claim 1, wherein in the test area, the metal pattern is located on the first organic film, and
the first organic film located in the test area comprises:
a first protrusion located to be in contact with the first metal pattern portion; and
a second protrusion located to be in contact with the second metal pattern portion.

4. The display device of claim 3, wherein the first metal pattern portion includes a bottom surface at least partially exposed by the first protrusion, and
the second metal pattern portion includes a bottom surface at least partially exposed by the second protrusion.

5. The display device of claim 3, wherein a length of a bottom surface of the first metal pattern portion exposed by the first protrusion is equal to a length of a bottom surface of the second metal pattern portion exposed by the second protrusion.

6. The display device of claim 3, wherein the test area has an undercut structure defined by a top surface of the first organic film, a side surface of the first protrusion, and a bottom surface of the first metal pattern portion.

7. The display device of claim 3, wherein a length of the first protrusion in the first direction is different from a length of the second protrusion in the first direction.

8. The display device of claim 3, wherein the first length is smaller than the second length, and
a length of the first protrusion in the first direction is smaller than a length of the second protrusion in the first direction.

9. The display device of claim 1, wherein in the test area, the metal pattern is located on the first organic film,
a first overlapping length and a second overlapping length are defined in the test area,
the first overlapping length is different from the second overlapping length,
the first overlapping length is a length in the first direction of a portion of a lower surface of the first metal pattern portion contacting the first organic film, and
the second overlapping length is a length in the first direction of a portion of a lower surface of the second metal pattern portion contacting the first organic film.

10. The display device of claim 1, wherein in the test area, the metal pattern is located on the first organic film,
a first exposure length and a second exposure length are defined in the test area,
the first exposure length is different from the second exposure length,
the first exposure length is a length in the first direction of a portion of a lower surface of the first metal pattern portion exposed by the first organic film, and
the second exposure length is a length in the first direction of a portion of a lower surface of the second metal pattern portion exposed by the first organic film.

11. The display device of claim 1, wherein in the test area, the metal pattern is located on the first organic film,
in the test area, a first overlapping length, a second overlapping length, a first exposure length, and a second exposure length are defined, and
a sum of the first overlapping length and the first exposure length is equal to a sum of the second overlapping length and the second exposure length,
the first overlapping length is a length in the first direction of a portion of a lower surface of the first metal pattern portion contacting the first organic film,
the second overlapping length is a length in the first direction of a portion of a lower surface of the second metal pattern portion contacting the first organic film,
the first exposure length is a length in the first direction of a portion of a lower surface of the first metal pattern portion exposed by the first organic film, and
the second exposure length is a length in the first direction of a portion of a lower surface of the second metal pattern portion contacting the first organic film.

12. The display device of claim 1, wherein in the test area, the metal pattern is located on the first organic film,
the metal pattern comprises a reference metal pattern portion having a reference length in the first direction,
the reference length is greater than the first length and the second length,
the first organic film located in the test area comprises a protrusion located to be in contact with the reference metal pattern portion, and
a region comprising the reference metal pattern portion has an undercut structure formed by a top surface of the first organic film, a side surface of the protrusion, and a bottom surface of the reference metal pattern portion.

13. The display device of claim 12, wherein the tip has a tip exposure length exposed by the first organic film, and
a length of a bottom surface of the reference metal pattern portion exposed by the protrusion is substantially the same as the tip exposure length.

14. The display device of claim 1, further comprising a display area comprising a plurality of pixels,
wherein the pixel comprises:
a first organic film;
a connection electrode located on the first organic film;
a second organic film located on the connection electrode;
a pixel electrode located on the second organic film;
a light emitting layer located on the pixel electrode; and
a common electrode located on the light emitting layer,
the inorganic encapsulation area has a groove defined between the plurality of tips, and
the inorganic encapsulation area further comprises:
a light emitting layer remnant located in the groove and including a same material as the light emitting layer; and
a common electrode remnant located on the light emitting layer remnant and including a same material as the common electrode.

15. The display device of claim 14, wherein the tip includes a same material as the connection electrode.

16. An electronic device comprising:
a processor which provides an image signal;
a display module which receives the image signal from the processor and displays an image; and
a power module which supplies power to the display module,
wherein the display module has a through hole defined therein,
wherein the display module comprises:
an inorganic encapsulation area located to surround the through hole and comprising a plurality of tips arranged on a first organic film; and
a test area comprising a metal pattern,
wherein the metal pattern includes a same material as the tips, and
the metal pattern comprises:
a first metal pattern portion having a first length in a first direction; and
a second metal pattern portion having a second length in the first direction, and
wherein the first length is different from the second length.

17. The electronic device of claim 16, wherein in the test area, the metal pattern is located on the first organic film, and
the first organic film located in the test area comprises:
a first protrusion located to be in contact with the first metal pattern portion; and
a second protrusion located to be in contact with the second metal pattern portion.

18. The electronic device of claim 17, wherein the test area comprises an undercut structure defined by a top surface of the first organic film, a side surface of the first protrusion, and a bottom surface of the first metal pattern portion.

19. The electronic device of claim 16, wherein in the test area, the metal pattern is located on the first organic film,
a first overlapping length and a second overlapping length are defined in the test area,
the first overlapping length is different from the second overlapping length,
the first overlapping length is a length in the first direction of a portion of a lower surface of the first metal pattern portion contacting the first organic film, and
the second overlapping length is a length in the first direction of a portion of a lower surface of the second metal pattern portion contacting the first organic film.

20. The electronic device of claim 16, wherein in the test area, the metal pattern is located on the first organic film,
a first exposure length and a second exposure length are defined in the test area,
the first exposure length is different from the second exposure length,
the first exposure length is a length in the first direction of a portion of a lower surface of the first metal pattern portion exposed by the first organic film, and
the second exposure length is a length in the first direction of a portion of a lower surface of the second metal pattern portion exposed by the first organic film.
